(19) United States
(12) Patent Application Publication
(10) Pub. No.: US 2009/0266583 A1
(43) Pub. Date: Oct. 29, 2009

(54) PHOTOSENSITIVE RESIN COMPOSITION, LAMINATE, METHOD OF PRODUCING METAL PLATED MATERIAL, METAL PLATED MATERIAL, METHOD OF PRODUCING METAL PATTERN MATERIAL, METAL PATTERN MATERIAL AND WIRING SUBSTRATE

(75) Inventors: Hideo Nagasaki, Kanagawa (JP); Takeyoshi Kano, Kanagawa (JP)

Correspondence Address: Moss & Burke, PLLC, 401 Holland Lane, Suite 407, Alexandria, VA, 22314, US

(73) Assignee: FUJIFILM CORPORATION, Tokyo (JP)

(21) Appl. No.: 12/426,964

(22) Filed: Apr. 21, 2009

(30) Foreign Application Priority Data
Apr. 23, 2008 (JP) 2008-113210
Jan. 14, 2009 (JP) 2009-006032
Mar. 31, 2009 (JP) 2009-086190

(51) Int. Cl. H05K 1/00; B05D 3/10; B32B 15/08; H01B 13/00; B32B 3/10; C08F 124/00; C08F 22/30; C08F 12/24

(52) U.S. Cl. 174/250; 427/333; 428/457; 216/13; 428/209; 526/273; 526/297; 526/313

(57) ABSTRACT

The invention provides a photosensitive resin composition comprising: a polymer comprising a polymerizable group and a functional group that interacts with a plating catalyst or a precursor thereof so as to form a coordination bond; and at least one selected from the group consisting of a synthetic rubber, an epoxy acrylate monomer, and a polymerizable monomer having a benzyl alcohol group; a laminate; a method of producing a metal plated material; a metal plated material; a method of producing a metal pattern material; a metal pattern material; and a wiring substrate.

### CROSS-REFERENCE TO RELATED APPLICATION

This application claims priority under 35 USC 119 from Japanese Patent Application Nos. 2008-113210, 2009-006032 and 2009-086190, the disclosure of which is incorporated by reference herein.

### BACKGROUND OF THE INVENTION

1. Field of the Invention

The invention relates to a photosensitive resin composition, a laminate, a method of producing a metal plated material, a metal plated material, a method of producing a metal pattern material, a metal pattern material, and a wiring substrate.

2. Description of the Related Art

Conventionally, a metal wiring substrate having wiring made of a metal pattern formed on an insulating substrate has been widely used for electronic members or semiconductor devices.

Such a metal pattern material is produced mainly by a subtractive method. The subtractive method includes forming a photosensitive layer that is sensitive to radiation of actinic rays on a metal film that has been formed on a substrate; exposing the photosensitive layer to light in an image-wise manner; developing the same to form a resist image; etching the metal film to form a metal pattern; and then removing the resist.

In the metal pattern obtained by the above method, the metal film is adhered to the substrate by an anchoring effect that occurs due to irregularities formed on the substrate surface. Therefore, there is a problem in that high-frequency characteristics of the metal pattern when used as a metal wiring may deteriorate due to the irregularities formed at the interface of metal pattern and substrate. Further, since the substrate surface needs to be treated with a strong acid such as chromium acid to be roughened, it is necessary to perform a complicated process in order to obtain a metal pattern having excellent adhesiveness between a metal film and a substrate.

Moreover, as demands for more sophisticated electronic apparatuses increase, large scale integration or high density packaging of the electronic devices has advanced, and miniaturization or density growth of a printed wiring substrate used for these devices has also progressed.

A flexible resin film substrate with a metal layer formed thereon is commonly used as a substrate onto which a driving semiconductor that displays an image on a liquid crystal display is mounted, or a substrate used for a driving section that needs to be flexible. In recent years, COFs (chip on film) have attracted attention as a technique of mounting a driver IC chip for liquid crystal display. The COFs are considered to be applicable to fine-pitch packaging and capable of reducing the size of ICs and cost, as compared with conventional TCPs (tape carrier package). As the fineness of liquid crystal display increases and the size of ICs for driving the liquid crystal reduces, there is a strong desire for an electronic circuit for COFs having improved fineness and fine pitch.

Japanese Patent Application Laid-Open No. 2008-7756 proposes a viscoelastic resin composition including glycigyl methacrylate, a synthetic rubber having a specific property, and a curable component, as a composition for an interlayer insulating material suitable for a flexible resin film substrate. This resin composition is flexible and useful as an interlayer insulating material. However, when a metal film is formed on the substrate, sufficient adhesiveness may not be achieved if surface roughening is not performed. Therefore, this resin composition is not suitable for the formation of fine wiring.

Additionally, when a wiring pattern is formed on a flexible substrate or an insulating resin film, adhesiveness between the wiring pattern and the substrate or insulating resin film is an important factor. For example, when a layer of polyimide varnish is formed as an insulating resin on a copper foil to produce a resin film with a metal layer by thermal reaction, the adhesiveness depends on the adhesion between the copper foil and the polyimide varnish layer. However, when the surface of copper foil is roughened to cause adhesion due to an anchoring effect, there is a problem in that sufficient adhesiveness may not be achieved when the size of irregularities needs to be small so as not to affect the configuration of wiring having small wiring lines and wiring intervals. On the other hand, when a copper foil is formed on the polyimide by sputtering, sufficient adhesiveness may not be achieved. Further, the production cost may increase since the sputtering is performed by a vacuum apparatus and the film formation speed is slow.

In order to overcome the above problems, Advanced Materials (2000), Vol. 20, pages 1481-1494 proposes a method of improving adhesiveness between a substrate and a metal film without roughening the substrate surface. This method includes performing a plasma treatment to the substrate surface and introducing a functional group that initiates polymerization to the substrate surface, forming a monomer from the functional group, and then forming a surface graft polymer having a polar group on the substrate surface. However, in this method, since the graft polymer has a polar group, absorption or desorption of moisture due to changes in temperature or humidity tends to occur, which may cause deformation of the obtained metal film or the substrate.

Additionally, when the metal pattern obtained by this method is used for wiring of a metal wiring substrate, the graft polymer having a polar group may remain at an interface of the substrate tends and retain moisture or ions, which may affect properties dependent on temperature or humidity, anti-ion migration properties between the wirings, or deformation.

In particular, when the metal pattern is used for wiring having a fine configuration such as a printed wiring substrate, a high level of insulating property between the wirings (metal pattern) is required. Therefore, further improvement in insulating reliability between the wirings is highly demanded.

JP-A No. 58-196238 proposes a method of performing surface modification by grafting a radical-polymerizable compound to the substrate surface for the purpose of suppressing the size of irregularities on the substrate to a minimum level and simplifying the treatment process of the substrate. However, in this method, an expensive apparatus (such as a γ-ray generator or an electron beam generator) is required. Further, since a typical plastic substrate that can be commercially obtained is used for the substrate, generation of a graft polymer on the substrate surface is not sufficient enough to tightly adhere a conductive material thereto, thereby failing to achieve a practically tolerable adhesiveness between the substrate and the conductive layer.

Moreover, JP-A 2007-131875 proposes a method of using a polymer having a functional group that interacts with a metal ion or the like, from the viewpoint of adhesiveness to a metal film. Since this polymer has many polar groups in a molecule, it exhibits excellent adhesiveness and is useful for the formation of fine wiring. However, there is a need for further improvement in insulating reliability between the wirings.

Accordingly, there is a desire for a technique of forming a metal film that can achieve practically tolerable adhesiveness, excellent insulation properties between the fine wirings, and can be applied to a flexible substrate.

### SUMMARY OF THE INVENTION

An aspect of the invention provides a photosensitive resin composition comprising: a polymer comprising a polymerizable group and a functional group that interacts with a plating catalyst or a precursor thereof so as to form a coordination bond; and at least one selected from the group consisting of a synthetic rubber, an epoxy acrylate monomer, and a polymerizable monomer having a benzyl alcohol group.

### DETAILED DESCRIPTION OF THE INVENTION

### Photosensitive Resin Composition for Plating

The photosensitive resin composition that is used for plating in the invention includes a compound containing a polymerizable group and a functional group that interacts with a plating catalyst or a precursor thereof so as to form a coordination bond (hereinafter, referred to as “specific compound” sometimes”) and at least one selected from the group consisting of a synthetic resin, an epoxy acrylate monomer and a polymerizable monomer having a benzyl alcohol group.

The specific compound may be a monomer, a macromer or a polymer. Among these, the specific compound is preferably a polymer containing a polymerizable group and a functional group that interacts with a plating catalyst or a precursor thereof so as to form a coordination bond (hereinafter, referred to as “specific polymer” sometimes”) in view of formation properties of a resin composition layer and ease of controlling the same. In the following, the specific polymer that may be used in the invention is described.

<Specific Polymer>

The specific polymer has a functional group that interacts with a plating catalyst or a precursor thereof to form a coordination linkage (hereinafter, referred to as “interactive group sometimes). Therefore, the specific polymer may efficiently adsorb the plating catalyst or the like. Further, since the specific polymer has a polymerizable group that can directly chemically bond to an arbitrary resin layer or a substrate, it may form a resin layer for plating that is tightly bonded to an arbitrary substrate or an insulating resin layer.

The resin layer preferably satisfies any one of the following requirements (1) to (4), more preferably satisfies all of the following requirements (1) to (4).

(1) The saturated water absorption rate as measured in an environment of 25° C.-50% relative humidity is 0.01 to 10% by mass;

(2) The saturated water absorption rate as measured in an environment of 25° C.-95% relative humidity is 0.05 to 20% by mass;

(3) The water absorption rate as measured after immersing the resin layer for one hour in boiling water at 100° C. is 0.1 to 30% by mass; and

(4) The surface contact angle as measured 15 seconds after dropping 5 μL of distilled water on the resin layer, in an environment of 25° C.-50% relative humidity, is 50 to 150 degrees.

In the invention, when the specific compound is used to generate a graft polymer by a surface graft polymerization method, it is preferable that the resin composition layer that is formed from the generated graft polymer is formed from a compound having a polymerizable group and an interactive group, as well as having low water absorbency and high hydrophobicity, such that all of the above requirements (1) to (4) are satisfied.

Examples of the interactive group include a non-dissociative functional group such as a functional group capable of multidentate coordination, a nitrogen-containing functional group, a sulfur-containing functional group, and an oxygen-containing functional group. The non-dissociative functional group refers to a functional group that does not generate a proton upon dissociation.

Such a functional group has a function of interacting with a plating catalyst or a precursor thereof, but does not have high water absorption or hydrophilicity such as those of a dissociative polar group (hydrophilic group). Therefore, a polymer layer formed from a graft polymer having the above functional group may satisfy the above requirements (1) to (4).

The polymerizable group in the invention refers to a functional group that bonds the specific compound to another specific compound or to a substrate upon application of energy. Specific examples of the polymerizable group include a vinyl group, a vinyloxy group, an allyl group, an acryloyl group, a methacryloyl group, an oxetane group, an epoxy group, an isocyanate group, a functional group containing active hydrogen, and an active group in an azo compound.

The interactive group in the invention is a functional group capable of interacting with a metal ion via a coordinate bond, preferably a non-dissociative functional group such as a functional group capable of coordinating with a metal ion, a nitrogen-containing functional group, a sulfur-containing functional group, and an oxygen-containing functional group. Specific examples thereof include nitrogen-containing functional groups such as an imide group, a pyridine group, a tertiary amino group, an ammonium group, a pyrrolidone group, an amidino group, a triazine group, a triazole group, a benzotriazol group, a benzoimidazole group, a quinoline group, a pyrimidine group, a pyrazine group, a quinazoline group, a quinoxaline group, a purine group, a triazine group, a piperidine group, a piperazine group, a pyrrolidine group, a pyrazole group, an aniline group, a group having an alkylamine group structure, a group having an isocyanuric structure, a nitro group, a nitroso group, an azo group, a diazo group, an azide group, a cyano group and a cyanate (R—O—CN) group; oxygen-containing functional groups such as a hydroxyl group, a carbonate group, an ether group, a carbonyl group, an ester group, a group having an N-oxide structure, a group having an S-oxide structure and a group having an N-hydroxy structure; sulfur-containing functional groups such as a thiophene group, a thiol group, a thiocyanuric acid group, a benzothiazole group, a mercaptotriazine group, a thioether group, a thioxy group, a sulfoxide group, a sulfonic group, a sulfite group, a group having a sulfoximine structure, a group having a sulfoxonium salt structure, and a group having a sulfonic acid ester structure; phosphorus-containing functional groups such as a phosphate group, a phosphoramide group and a phosphine group; groups containing a halogen atom such as chlorine or bromine; and groups containing an unsaturated ethylenic bond. An imidazole group, a urea group or a thiourea group are also applicable if the group acts as a non-dissociative functional group with respect to an adjacent atom or atomic group. Further, a functional group derived from a compound capable of forming a clathrate such as cyclodextrin or crown ether.

Among them, an ether group (more specifically, a group having a structure represented by —O—(CH₂)n-O— where n is an integer of from 1 to 5) or a cyano group is particularly preferred from the viewpoint of having high polarity and high adsorption capacity to a plating catalyst or the like, and a cyano group is most preferred.

In general, as the polarity increases, the water absorption rate tends to increase. However, since cyano groups interact with each other so as to cancel the polarity thereof in the resin composition layer, the film becomes dense and the polarity of the resin composition layer as a whole decreases, thereby reducing the water absorbancy. Further, by adsorbing the catalyst by a good solvent used for the resin composition layer, the cyano groups are solvated to cancel the interaction between the same, thereby enabling the cyano groups to interact with the plating catalyst. For the above reasons, the resin composition layer preferably contains a cyano group in order to achieve both of the contradicting properties, i.e., low water absorbency and favorable interaction with a plating catalyst.

The interactive group according to the invention is more preferably an alkylcyano group. This is because when the cyano group is bonded to an aromatic ring, electrons are attracted to the aromatic ring to decrease the donating property of unpaired electrons that play an important role for the adsorbability to a plating catalyst or the like. Therefore, an alkylcyano group, which is not bonded to an aromatic ring, is preferable in view of adsorbability to a plating catalyst or the like.

As mentioned above, the specific compound in the invention may be a monomer, a macromer or a polymer. Among these, the specific compound is preferably a polymer containing a polymerizable group and a functional group that interacts with a plating catalyst or a precursor thereof so as to form a coordination bond (hereinafter, referred to as “specific polymer” sometimes”) in view of formation properties of a resin composition layer and ease of controlling the same.

The specific polymer is preferably a polymer obtained from introducing an ethylene addition-polymerizable unsaturated group (polymerizable group) such as a vinyl group, an allyl group or a meth(acryloyl) group, into a homopolymer or copolymer formed from a monomer having an interactive group. The specific polymer preferably has a polymerizable group at least in a distol end of the main chain or in a side chain, more preferably in a side chain.

The monomer having an interactive group that is used for obtaining the specific polymer may be any monomer having the aforementioned non-dissociative functional group, and examples thereof are described in paragraph [0081] to [0084] of JP-A No. 2009-7662. The monomer may be used alone or in combination of two or more.

The specific polymer preferably includes a unit derived from a monomer having an interactive group preferably at an amount of 50 to 95 mol %, more preferably 40 to 80 mol %, from the viewpoint of interaction properties with a plating catalyst or a precursor thereof.

The method of synthesizing the specific polymer is described in, for example, paragraph [0085] to [0089] of JP-A No. 2009-7662, which may be applied to the invention.

Specific examples of the specific polymer are described in, for example, paragraph [009] to [0093] of JP-A No. 2009-7662, but the invention is not limited thereto.

In the invention, the specific polymer is preferably a polymer having a cyano group (hereinafter, referred to as a “cyano group-containing polymerizable polymer” sometimes).

The cyano group-containing polymerizable polymer is, for example, preferably a copolymer including a unit represented by the following formula (1) and a unit represented by the following formula (2).

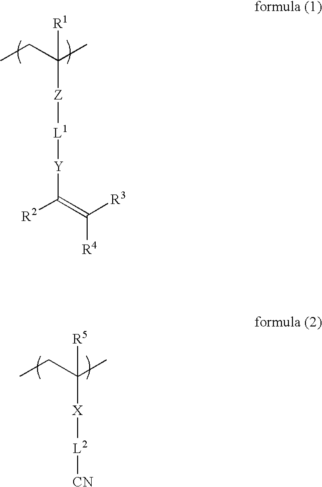

In formula (1) and formula (2), R¹ to R⁵ each independently represent a hydrogen atom, or a substituted or unsubstituted alkyl group; X, Y and Z each independently represent a single bond, a substituted or unsubstituted divalent organic group, an ester group, an amide group, or an ether group; and L¹ and L² each independently represent a substituted or unsubstituted divalent organic group.

When R¹ to R⁵ are a substituted or unsubstituted alkyl group, the unsubstituted alkyl groups include a methyl group, an ethyl group, a propyl group or a butyl group, and the substituted alkyl groups include a methyl group, an ethyl group, a propyl group or a butyl group, which is substituted by a methoxy group, a hydroxyl group, a chlorine atom, a bromine atom, a fluorine atom or the like.

R¹ is preferably a hydrogen atom, a methyl group, or a methyl group substituted by a hydroxyl group or a bromine atom.

R² is preferably a hydrogen atom, a methyl group, or a methyl group substituted by a hydroxyl group or a bromine atom.

R³ is preferably a hydrogen atom.

R⁴ is preferably a hydrogen atom.

R⁵ is preferably a hydrogen atom, a methyl group, or a methyl group substituted by a hydroxyl group or a bromine atom.

When X, Y and Z are a substituted or unsubstituted divalent organic group, examples of the divalent organic group include a substituted or unsubstituted aliphatic hydrocarbon group, or a substituted or unsubstituted aromatic hydrocarbon group.

The substituted or unsubstituted aliphatic hydrocarbon group is preferably a methylene group, an ethylene group, a propylene group, a butylene group, or these groups substituted by a methoxy group, a hydroxyl group, a chlorine atom, a bromine atom, a fluorine atom or the like.

The substituted or unsubstituted aromatic hydrocarbon groups is preferably an unsubstituted phenyl group, or a phenyl group substituted by a methoxy group, a hydroxyl group, a chlorine atom, a bromine atom, a fluorine atom, or the like.

Among them, —(CH₂)ₙ— (n is an integer of 1 to 3) is preferred, and more preferred is —CH₂—.

L¹ is preferably a divalent organic group having a urethane bond or a urea bond, more preferably a divalent organic group having a urethane bond. The divalent organic group having a urethane bond or a urea bond is particularly preferably one having a total number of carbon atoms of 1 to 9. Here, the total number of carbon atoms of L¹ means the total number of carbon atoms contained in the substituted or unsubstituted divalent organic group represented by L¹.

More specifically, the structure of L¹ is preferably a structure represented by the following formula (1-1) or formula (1-2).

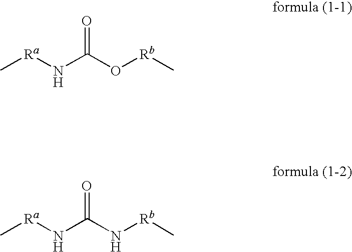

In formula (1-1) and formula (1-2), R^{a} and R^{b} each independently represent a divalent organic group formed from two or more atoms selected from the group consisting of a carbon atom, a hydrogen atom and an oxygen atom. Preferred examples thereof include a methylene group, an ethylene group, a propylene group or a butylene group, an ethylene oxide group, a diethylene oxide group, a triethylene oxide group, a tetraethylene oxide group, a dipropylene oxide group, a tripropylene oxide group, and a tetrapropylene oxide group.

L² is preferably a linear, branched or cyclic alkylene group, an aromatic group, or a group formed from a combination of these groups. The group formed from a combination of an alkylene group and an aromatic group may further include an ether group, an ester group, an amide group, a urethane group or a urea group therebetween. Among them, L² is preferably a group having a total number of carbon atoms of 1 to 15, particularly preferably having no substituent. Here, the total number of carbon atoms of L² means the total number of carbon atoms contained in the substituted or unsubstituted divalent organic group represented by L².

Specific examples of the substituted or unsubstituted divalent organic group represented by L² include a methylene group, an ethylene group, a propylene group, a butylene group, a phenylene group, these groups substituted by a methoxy group, a hydroxyl group, a chlorine atom, a bromine atom, a fluorine atom or the like, and a group formed from a combination of these groups.

In the cyano group-containing polymerizable polymer of the invention, the unit represented by formula (1) is preferably a unit represented by the following formula (3).

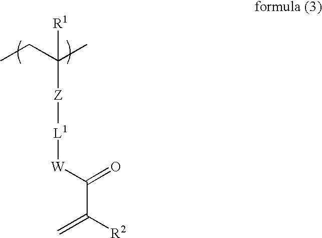

In formula (3), R¹ and R² each independently represent a hydrogen atom, or a substituted or unsubstituted alkyl group; Z represents a single bond, a substituted or unsubstituted divalent organic group, an ester group, an amide group, or an ether group; W represents an oxygen atom, or NR (wherein R represents a hydrogen atom or an alkyl group, preferably a hydrogen atom or an unsubstituted alkyl group having 1 to 5 carbon atoms); and L¹ represents a substituted or unsubstituted divalent organic group.

R¹ and R² in formula (3) have the same definitions as R¹ and R² in formula (1), and the same applies to the preferred examples thereof.

Z in formula (3) has the same definitions as Z in formula (1), and the same applies to the preferred examples thereof.

L¹ in formula (3) has the same definitions as L¹ in formula (1), and the same applies to the preferred examples thereof.

In the cyano group-containing polymerizable polymer of the invention, the unit represented by formula (3) is preferably a unit represented by the following formula (4).

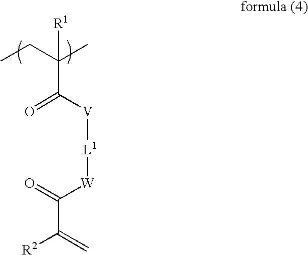

In formula (4), R¹ and R² each independently represent a hydrogen atom, or a substituted or unsubstituted alkyl group; V and W each independently represent an oxygen atom, or NR (wherein R represents a hydrogen atom or an alkyl group, preferably a hydrogen atom or an unsubstituted alkyl group having 1 to 5 carbon atoms); and L¹ represents a substituted or unsubstituted divalent organic group.

R¹ and R² in formula (4) have the same definitions as R¹ and R² in formula (1), and the same applies to the preferred examples thereof.

L¹ in formula (4) has the same definitions as L¹ in formula (1), and the same applies to the preferred examples thereof.

In formula (3) and formula (4), W is preferably an oxygen atom.

In formula (3) and formula (4), L¹ is preferably an unsubstituted alkylene group, or a divalent organic group having a urethane bond or a urea bond, more preferably a divalent organic group having a urethane bond. Among these, one having a total number of carbon atoms of 1 to 9 is particularly preferred.

In the cyano group-containing polymerizable polymer of the invention, the unit represented by formula (2) is preferably a unit represented by the following formula (5).

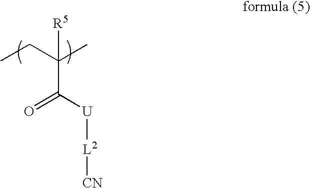

In formula (5), R⁵ represents a hydrogen atom, or a substituted or unsubstituted alkyl group; U represents an oxygen atom, or NR′ (wherein R′ represents a hydrogen atom or an alkyl group, preferably a hydrogen atom or an unsubstituted alkyl group having 1 to 5 carbon atoms); and L² represents a substituted or unsubstituted divalent organic group.

R⁵ in formula (5) has the same definitions as R¹ and R² in formula (1), and is preferably a hydrogen atom.

L² in formula (5) has the same definitions as L² in formula (1), and is preferably a linear, branched or cyclic alkylene group, an aromatic group, or a group formed from a combination of these groups.

In particular, in formula (5), the linkage site to the cyano group in L² is preferably a divalent organic group having a linear, branched or cyclic alkylene group, more preferably one having the total number of carbon atoms of 1 to 10.

In another preferred exemplary embodiment, the linkage site to the cyano group in L² in formula (5) is preferably a divalent organic group having an aromatic group, more preferably one having the total number of carbon atoms of 6 to 15.

The cyano group-containing polymerizable polymer of the invention includes a unit represented by any of formula (1) to formula (5), and is a polymer having a polymerizable group and a cyano group in a side chain thereof.

This cyano group-containing polymerizable polymer may be synthesized, for example, by the following method.

The type of polymerization reaction in the synthesis of the cyano group-containing polymerizable polymer of the invention includes radical polymerization, cationic polymerization and anionic polymerization. From the viewpoint of the reaction control, radical polymerization or cationic polymerization is preferable.

The synthesis method of cyano group-containing polymerizable polymer of the invention is different according to whether 1) the mode of polymerization of the polymer main chain is different from that of the polymerizable group to be introduced into the side chain; or 2) the mode of polymerization of the polymer main chain is the same as that of the polymerizable group to be introduced into the side chain. Details of the synthesis method of the cyano group-containing polymerizable polymer are described in paragraphs [0120] to [0164] of JP-A No. 2009-7662, which may be applied to the invention.

The cyano group-containing polymerizable polymer of the invention synthesized by the method as described in JP-A No. 2009-7662 preferably include a polymerizable group-containing unit and a cyano group-containing unit at the following ratio with respect to the total amount of copolymerization components, respectively.

The ratio of polymerizable group-containing unit is preferably 5 to 50 mol %, more preferably 5 to 40 mol %, with respect to the total amount of copolymerization components. If the above amount is less than 5 mol %, reactivity (curability or polymerizability) may not be sufficient, while if the above amount is more than 50 mol %, gelation may occur to hinder the synthesis.

The ratio of cyano group-containing unit is preferably 5 to 95 mol %, more preferably in 10 to 95 mol %, with respect to the total amount of copolymerization components, from the viewpoint of adsorbability to a plating catalyst or the like.

In addition, the cyano group-containing polymerizable polymer of the invention may further include a unit other than the cyano group-containing unit and the polymerizable group-containing unit. The monomer used for the formation of such a unit may be any monomer as long as it does not impair the effects of the invention.

Specific examples of the monomer used in the formation of a unit other than the cyano group-containing unit and the polymerizable group-containing unit include a monomer capable of forming a main chain skeleton, such as an acrylic resin skeleton, a styrene resin skeleton, a phenol resin (phenol-formaldehyde resin) skeleton, a melamine resin (a polycondensation product formed from melamine and formaldehyde) skeleton, a urea resin (a polycondensation product of urea and formaldehyde) skeleton, a polyester resin skeleton, a polyurethane skeleton, a polyimide skeleton, a polyolefin skeleton, a polycycloolefin skeleton, a polystyrene skeleton, a polyacrylic skeleton, an ABS (a polymer of acrylonitrile, butadiene and styrene) skeleton, a polyamide skeleton, a polyacetal skeleton, a polycarbonate skeleton, a polyphenylene ether skeleton, a polyphenylene sulfide skeleton, a polysulfone skeleton, a polyether sulfone skeleton, a polyaryl skeleton, a polyarylate skeleton, a polyether ether ketone skeleton, and a polyamide imide skeleton. These main chain skeletons may be a main chain skeleton of the cyano group-containing unit or the polymerizable group-containing unit.

When the polymer main chain is formed by radical polymerization, examples of the monomer that may be used include unsubstituted (meth)acrylic acid esters such as ethyl (meth)acrylate, butyl (meth)acrylate, hexyl (meth)acrylate, 2-ethylhexyl (meth)acrylate, cyclohexyl (meth)acrylate, benzyl (meth)acrylate and stearyl (meth)acrylate; halogen-substituted (meth)acrylic acid esters such as 2,2,2-trifluoroethyl (meth)acrylate, 3,3,3-trifluoropropyl (meth)acrylate and 2-chloroethyl (meth)acrylate; ammonium group-substituted (meth)acrylic acid esters such as 2-(meth)acryloyloxyethyltrimethylammonium chloride; (meth)acrylamides such as butyl(meth)acrylamide, isopropyl(meth)acrylamide, octyl(meth)acrylamide and dimethyl(meth)acrylamide; styrenes such as styrene, vinyl benzoate and p-vinylbenzylammonium chloride; vinyl compounds such as N-vinylcarbazole, vinyl acetate, N-vinylacetamide and N-vinylcaprolactam; and dimethylaminoethyl (meth)acrylate, diethylaminoethyl (meth)acrylate, 2-ethylthio-ethyl (meth)acrylate, (meth)acrylic acid, 2-hydroxyethyl (meth)acrylate, and the like.

Macromonomers obtained from the above monomers may also be used.

When the polymer main chain is formed by cationic polymerization, examples of the monomer that may be used include vinyl ethers such as ethyl vinyl ether, butyl vinyl ether, isobutyl vinyl ether, cyclohexyl vinyl ether, ethylene glycol vinyl ether, di(ethylene glycol) vinyl ether, 1,4-butanediol vinyl ether, 2-chloroethyl vinyl ether, 2-ethylhexyl vinyl ether, vinyl acetate, 2-vinyloxytetrahydropyran, vinyl benzoate and vinyl butyrate; styrenes such as styrene, p-chlorostyrene and p-methoxystyrene; and terminal ethylenes such as allyl alcohol and 4-hydroxy-1-butene.

The weight average molecular weight of the cyano group-containing polymerizable polymer of the invention is preferably 1,000 or more and 700,000 or less, more preferably 2,000 or more and 200,000 or less. In particular, from the viewpoint of polymerization sensitivity, the weight average molecular weight of the cyano group-containing polymerizable polymer of the invention is preferably 20,000 or more.

Regarding the degree of polymerization of the cyano group-containing polymerizable polymer of the invention, the polymer is preferably a decamer or more, more preferably a 20-mer or more. Further, the polymer is preferably a 7000-mer or less, more preferably a 3000-mer or less, even more preferably a 2000-mer or less, and particularly preferably a 1000-mer or less.

The preferable ranges of weight average molecular weight and degree of polymerization as mentioned above are also applicable to the specific polymer other than the cyano group-containing polymerizable group.

Specific examples of the cyano group-containing polymerizable polymer of the invention will be shown below, but the invention is not limited thereto.

The weight average molecular weight of all of these specific examples is in the range of 3,000 to 100,000.

1-1) Polymers Having a Polymer Main Chain Form Cationic Polymerization and a Polymerizable Group to be Introduced in a Side Chain that is Radical Polymerizable

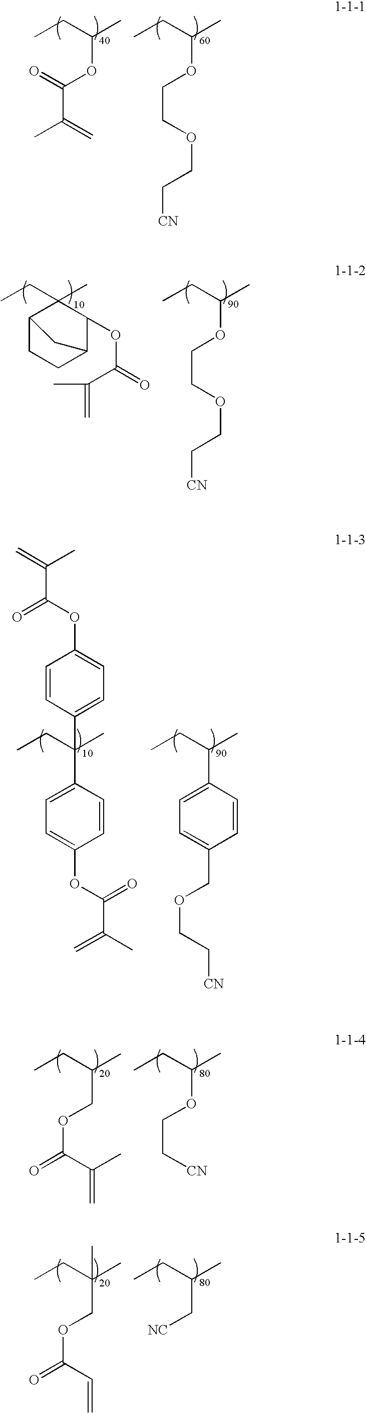

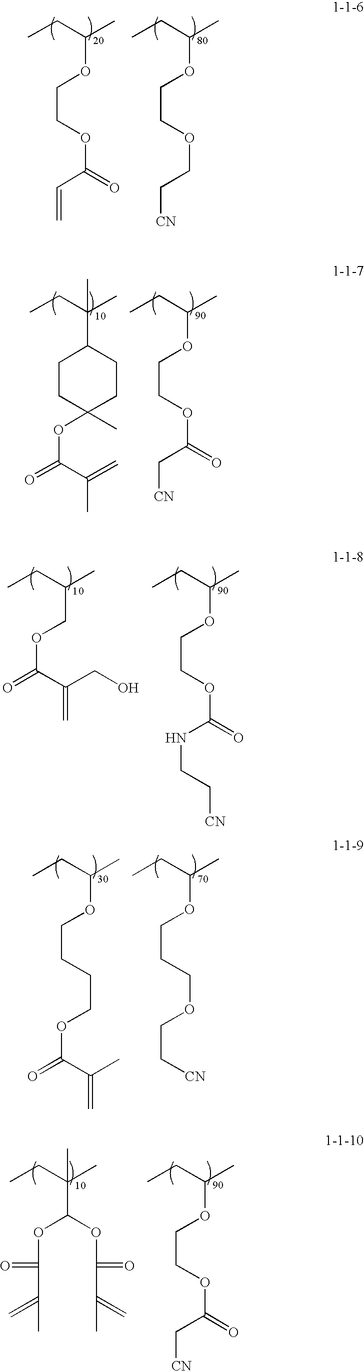

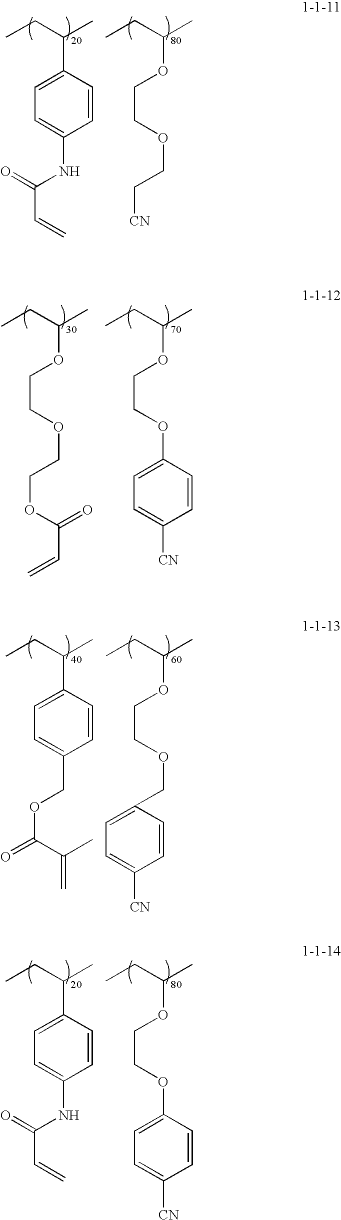

1-2) Polymers Having a Polymer Main Chain Form Radical Polymerization and a Polymerizable Group to be Introduced in a Side Chain that is Cationic Polymerizable

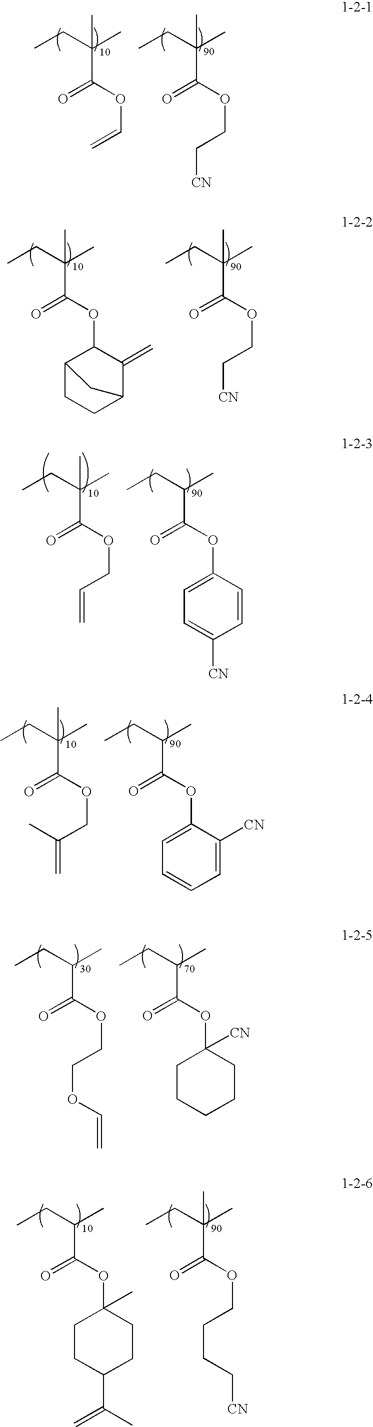

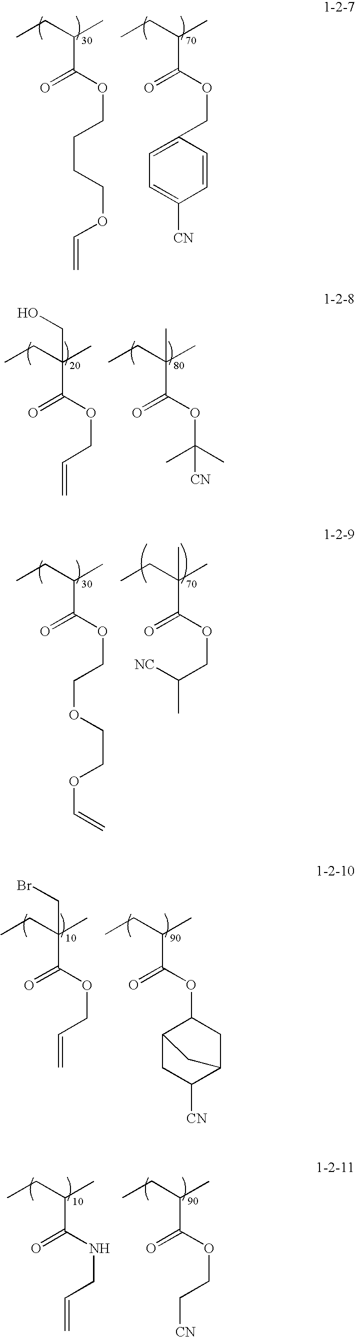

2-1) Polymers Having a Polymer Main Chain Form Cationic Polymerization and a Polymerizable Group to be Introduced in a Side Chain that is Cationic Polymerizable

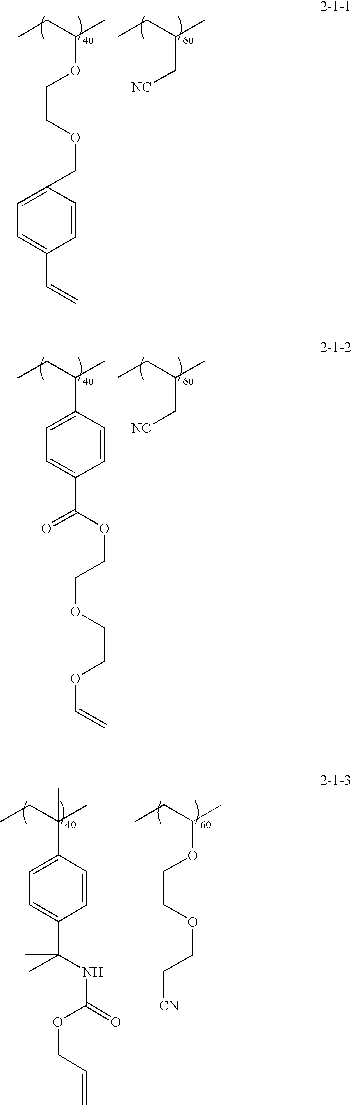

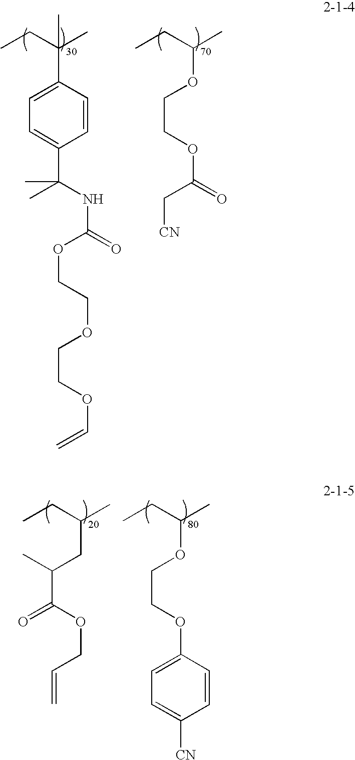

2-2) Polymers Having a Polymer Main Chain Form Radical Polymerization and a Polymerizable Group to be Introduced in a Side Chain that is Radical Polymerizable

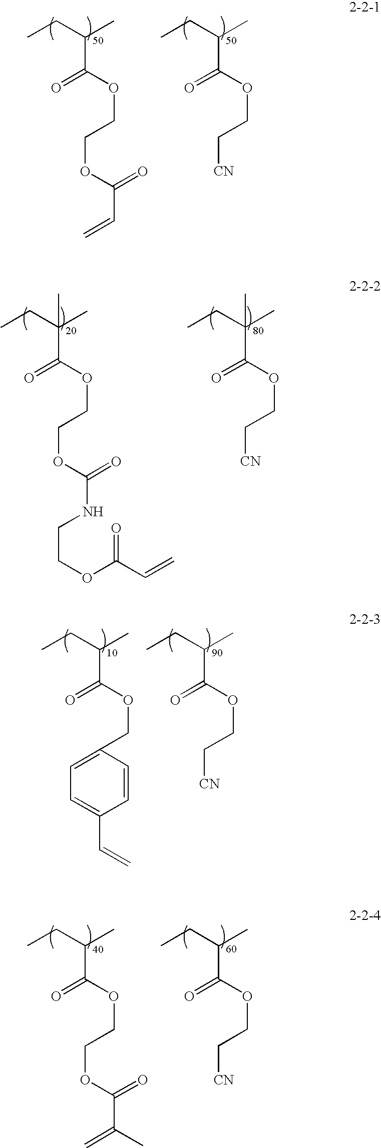

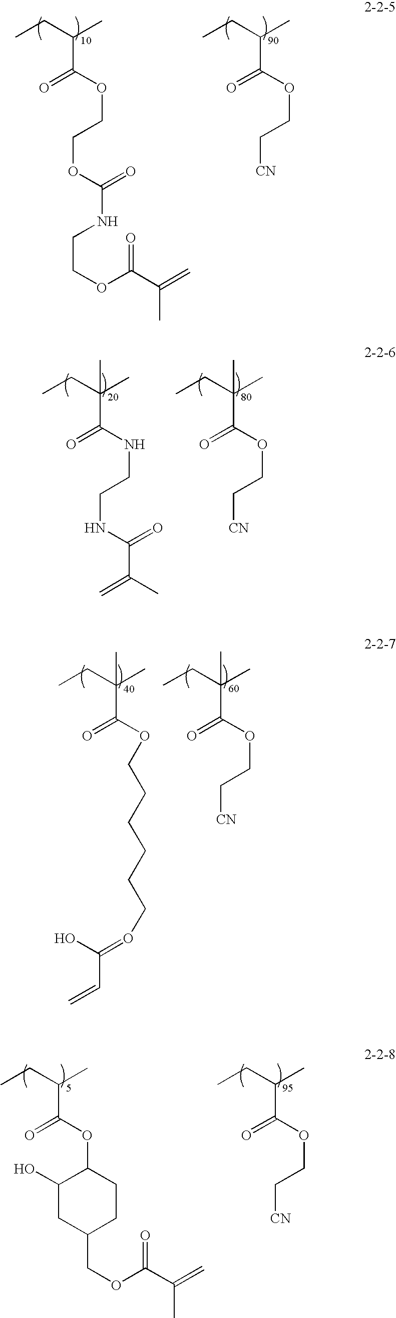

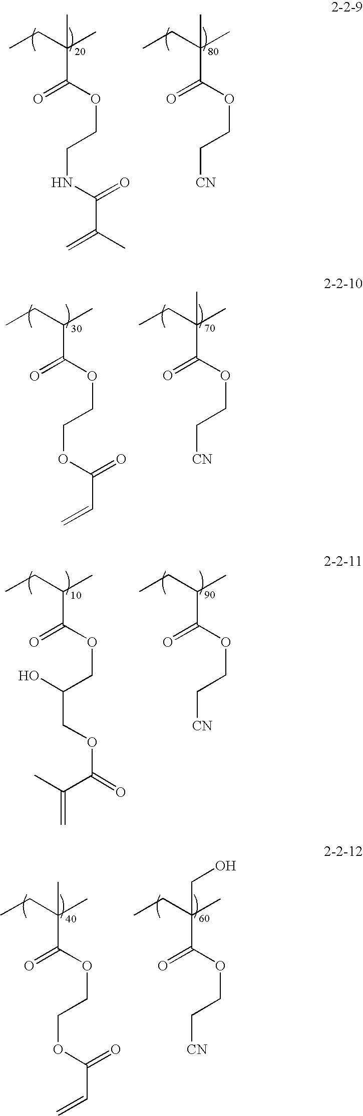

2-2) Polymers Having a Polymer Main Chain Form Radical Polymerization and a Polymerizable Group to be Introduced in a Side Chain that is Radical Polymerizable

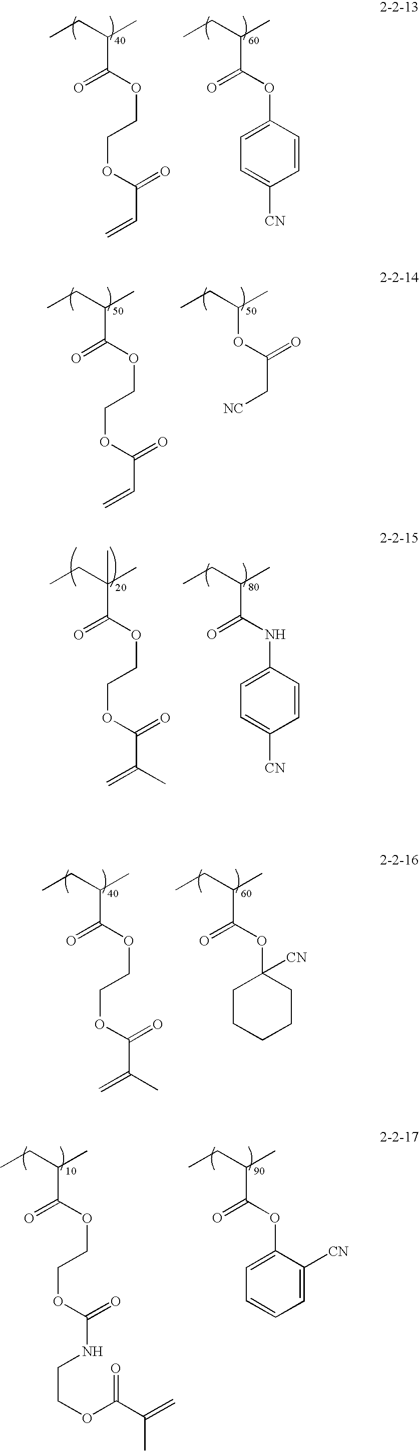

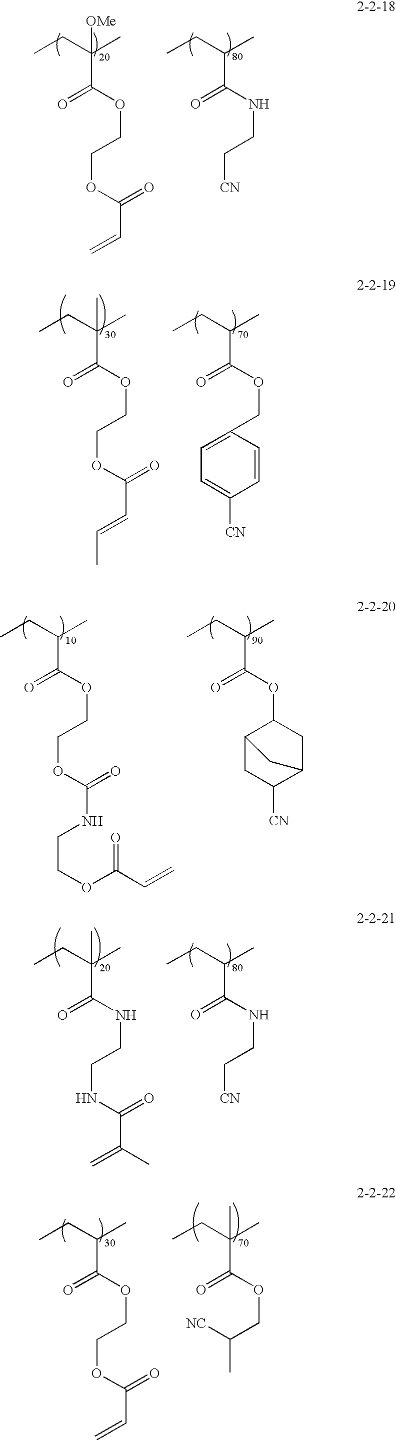

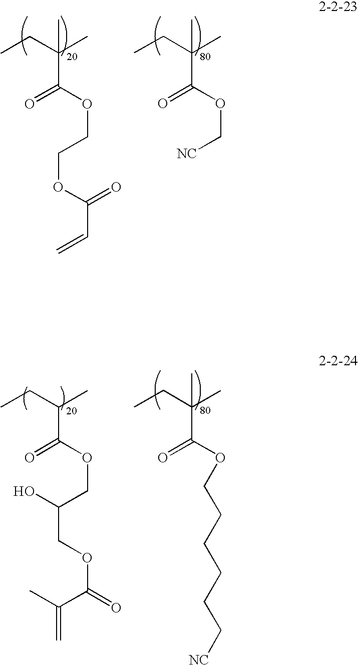

2-2) Polymers Having a Polymer Main Chain Form Radical Polymerization and a Polymerizable Group to be Introduced in a Side Chain that is Radical Polymerizable

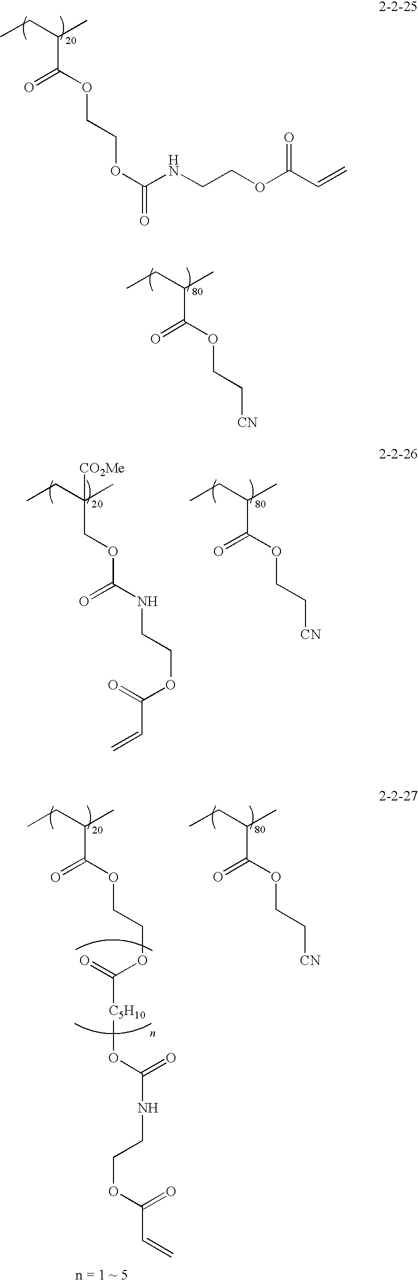

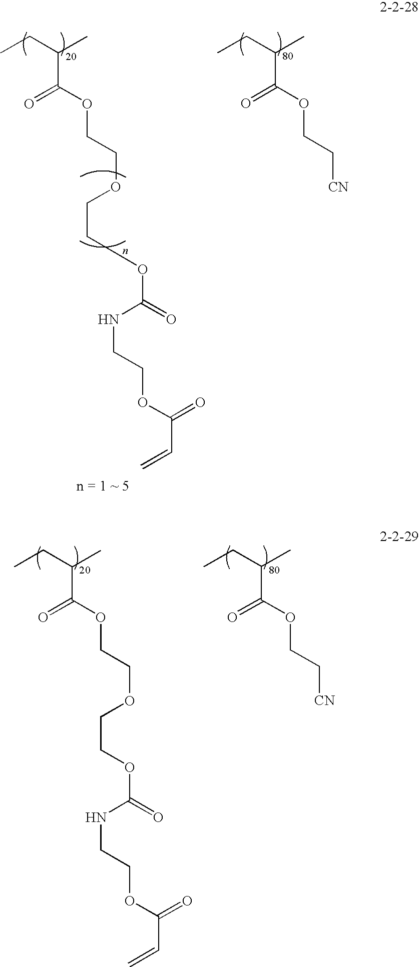

2-2) Polymers Having a Polymer Main Chain Form Radical Polymerization and a Polymerizable Group to be Introduced in a Side Chain that is Radical Polymerizable

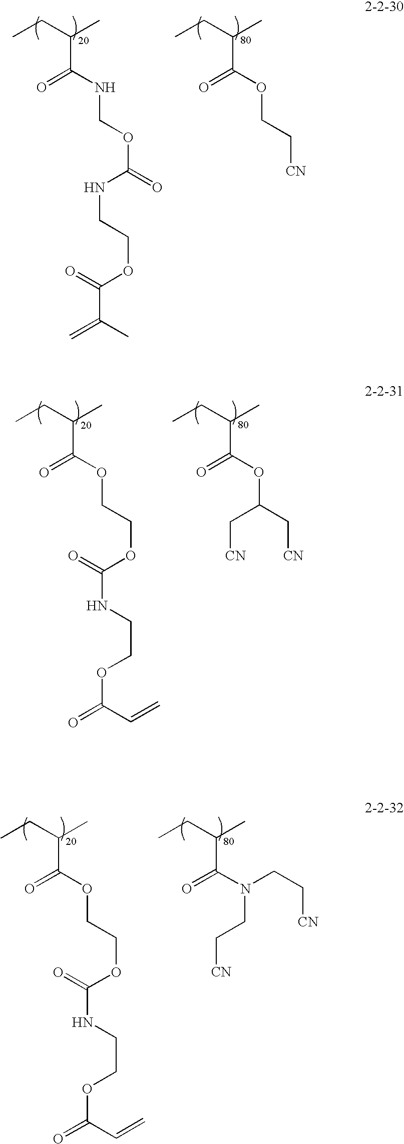

For example, Compound 2-2-11 shown in the above specific examples may be synthesized by dissolving acrylic acid and 2-cyanoethyl acrylate in N-methylpyrrolidone or the like, performing radical polymerization using azoisobutyronitrile (AIBN) or the like as a polymerization initiator, and then subjecting the resultant to addition reaction with glycidyl methacrylate using a catalyst such as benzyltriethylammonium chloride with the addition of a polymerization inhibitor such as tertiary-butylhydroquinone.

Further, for example, Compound 2-2-19 shown in the above specific examples may be synthesized by dissolving the following monomer and p-cyanobenzyl acrylate in a solvent such as N,N-dimethylacrylamide, performing radical polymerization using a polymerization initiator such as dimethyl azoisobutyrate, and then subjecting the resultant to dehydrochlorination using a base such as triethylamine.

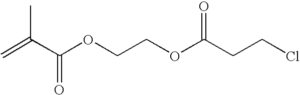

The specific compound, such as the cyano group-containing polymerizable polymer, may have a polar group other than the polymerizable group and interactive group. However, since the obtained resin preferably satisfies at least one of the aforementioned requirements (1) to (4), more preferably all of these requirements, it is preferable to control the type or amount to be introduced of the polar group.

When the polar group is included in the compound, adhesion at an interface between a metal film that is formed in the later-described plating process and a protection layer or the like that is optionally provided on the metal layer may be improved.

As described above, in order to form a resin composition layer according to the invention, it is preferable to use a photosensitive resin composition containing the specific compound, such as the specific polymer, and a solvent that can dissolve the specific compound (more preferably a photosensitive resin composition containing a polymer having a polymerizale group and a cyano group or —O—(CH₂)n-O— (n is an integer of 1 to 5), and a solvent that can dissolve the polymer).

When the specific compound is the specific polymer, the weight average molecular weight of the specific polymer is preferably 1,000 to 700,000, more preferably 2,000 to 300,000. In particular, from the viewpoint of polymerization sensitivity, the weight average molecular weight is 20,000 or more.

Regarding the degree of polymerization of the specific polymer of the invention, the polymer is preferably a decamer or more, more preferably a 20-mer or more. Further, the polymer is preferably a 7000-mer or less, more preferably a 3000-mer or less, even more preferably a 2000-mer or less, and particularly preferably a 1000-mer or less.

The content of the specific compound (such as a cyano group-containing polymerizable compound) is preferably from 2 to 50 mass %, more preferably from 5 to 20 mass %, with respect to the amount of the photosensitive resin composition.

The photosensitive resin composition includes, in addition to the specific compound (such as the specific polymer), at least one selected from a synthetic rubber, an epoxy acrylate monomer, and a polymeriable monomer having an benzyl alcohol group. By adding at least one of these compounds to the photosensitive resin composition, formation of high-definition pattern, flexibility of the film, or adhesiveness to a plating film may be improved even under severe conditions such as high humidity.

It may also be possible to improve the adhesion to an interlayer insulating film or a solder resist to be provided in the formation of a multilayer wiring substrate, by using the compound selected from the following three kinds.

<Synthetic Rubber>

The synthetic rubber that may be added to the photosensitive resin composition according to the invention is not particularly limited as long as it is a synthetic polymer having elasticity. The synthetic rubber preferably has a structure in which the main skeleton is formed from carbon atoms as a main component.

Examples of the synthetic rubber that may be used in the invention include a rubber having a polymethylene-type saturated main chain (Group M), a rubber having a main chain including a carbon atom and an oxygen atom (Group O), and a rubber having a main chain including an unsaturated carbon bond (Group R).

Examples of the rubber classified in Group M include an acrylic rubber (ACM), a rubber-like copolymer of ethyl acrylate or other acrylate and ethylene (AEM), a rubber-like copolymer of ethyl acrylate or other acrylate and acrylonitrile (ANM), chlorinated polyethylene (CM), chlorosulfonated polyethylene (CSM), a rubber-like copolymer of ethylene, propylene and diene (EPDM), a rubber-like copolymer of ethylene and propylene (EPM), a rubber-like copolymer of ethylene and vinyl acetate (EVM), polyisobutene or polyisobutylene (IM), a rubber-like copolymer of acrylonitrile and butadiene having a main chain that is completely hydrogenated (NBM), a rubber-like copolymer of styrene, ethylene and butene (SEBM), and a rubber-like copolymer of styrene, ethylene and propylene (SEPM).

Examples of the rubber classified in Group O include epichlorohydrin rubber (CO), a rubber-like copolymer of ethylene oxide and epichlorohydrin (ECO), a rubber-like copolymer of epichlorohydrin and allyl glycidyl ether (GCO), a rubber-like copolymer of ethylene oxide, epichlorohydrin and allyl glycidyl ether (GECO), and a rubber-like copolymer of propylene oxide and allyl glycidyl ether (GPO).

Examples of the rubber classified in Group R include acrylate butadiene rubber (ABR), butadiene rubber (BR), chloroprene rubber (CR), epoxidized natural rubber (ENR), hydrogenated nitrile rubber (HNBR), butyl rubber (IIR), synthetic natural rubber (IR), a rubber-like copolymer of methylstyrene and butadiene (MSBR), a rubber-like copolymer of acrylonitrile, butadiene and isoprene (NBIR), nitrile rubber (NBR), a rubber-like copolymer of acrilonitrile and isoprene (NIR), norbornene rubber (NOR), a rubber-like copolymer of vinylpyridine and butadiene (PBR), a rubber-like copolymer of vinylpyridine, styrene and butadiene (PSBR), a rubber-like copolymer of styrene and butadiene (SBR), a rubber-like copolymer of styrene and butadiene synthesized by emulsification polymerization (E-SBR), a rubber-like copolymer of styrene and butadiene synthesized by solution polymerization (S-SBR), a rubber-like copolymer of styrene, isoprene and butadiene (SIBR), carboxylated butadiene rubber (XBR), carboxylated chloroprene rubber (XCR), carboxylated rubber-like copolymer of styrene and butadiene (XNBR), brominated butyl rubber (BIIR), and chlorinated butyl rubber (CIIR).

Among these, the rubbers classified in Group R, more specifically nitrile rubber (NBR), styrene butadiene rubber (SBR), isoprene rubber (IR), butadiene rubber (BR) and chloroprene rubber (CR), are preferable. The weight average molecular weight of the rubber is preferably about 3,000 to 1,000,000. From the viewpoint of adsorbing a catalyst, NBR and SBR are preferable, and NBR is most preferable.

NBR may be obtained as a commercial product, such as NIPOL 1042 (trade name, manufactured by Zeon Corporation); and JSR N220S, PNR-1H and XER-91 (trade name, manufactured by JSR Corporation).

The synthetic rubber may be directly mixed with the specific compound (such as the specific polymer) while it is not vulcanized, or may be added as a dispersion.

The synthetic rubber may be used in the photosensitive resin composition alone or in combination of two or more. The amount of the synthetic rubber (solid content) is preferably 1 to 60 parts by mass, more preferably 5 to 50 parts by mass, yet more preferably 10 to 45 parts by mass, with respect to 100 parts by mass of the specific compound (such as the specific polymer) in terms of solid content.

<Epoxy Acrylate Monomer>

The epoxy acrylate monomer that may be used in the photosensitive resin composition of the invention is a monomer having an epoxy site and an acrylate site, such as glycidyl methacrylate, glycidyl acrylate and 3,4-epoxy cyclohexylmethyl acrylate. These monomers may be obtained as a commercial product, such as CYCLOMER A 400 (trade name, 3,4-epoxy cyclohexylmethyl acrylate, manufactured by Daicel Chemical Industries, Ltd.).

The epoxy acrylate monomer may be used in the photosensitive resin composition alone or in combination of two or more. The amount of the epoxy acrylate monomer (solid content) is preferably 1 to 60 parts by mass, more preferably 5 to 45 parts by mass, yet more preferably 10 to 35 parts by mass, with respect to 100 parts by mass of the specific compound (such as the specific polymer) in terms of solid content.

<Polymerizable Monomer Having Benzyl Alcohol Group>

The polymerizable monomer having a benzyl alcohol group that may be used in the invention may be any compound as long as it is a monomer having a benzyl alcohol site and a (meth)acrylate site. Examples thereof include 4-(meth)acryloyloxymethyl-benzyl alcohol, 3-(meth)acryloyloxymethyl-benzyl alcohol, 2-(meth)acryloyloxymethyl-benzyl alcohol, 4-(meth)acryloyloxy-benzyl alcohol, 3-(meth)acryloyloxy-benzyl alcohol, 2-(meth)acryloyloxy-benzyl alcohol, 1-hydroxymethyl-2-(meth)acryloyloxymethyl-naphthalene, 1-hydroxymethyl-3-(meth)acryloyloxymethyl-naphthalene, 1-hydroxymethyl-4-(meth)acryloyloxymethyl-naphthalene, 1-hydroxymethyl-5-(meth)acryloyloxymethyl-naphthalene, 1-hydroxymethyl-6-(meth)acryloyloxymethyl-naphthalene, 1-hydroxymethyl-7-(meth)acryloyloxymethyl-naphthalene, 1-hydroxymethyl-8-(meth)acryloyloxymethyl-naphthalene, 1-(meth)acryloyloxy-2,6-bis(hydroxymethyl)-benzene, 1-(meth)acryloyloxy-2,6-bis(hydroxymethyl)-4-methyl-benzene, 1-(meth)acryloyloxy-3,5-bis(hydroxymethyl)-benzene, and N-(meth)acryloyl-3,5-bis(hydroxymethyl)-aniline.

The photosensitive resin composition of the invention includes at least one selected from a synthetic rubber, and epoxy acrylate monomer and a polymerizable monomer having a benzyl alcohol group. However, by adding the synthetic rubber to the composition, insulation reliability between the obtained metal pattern or flexibility of the film may be further improved, and is thus suitable for use in a flexible wiring substrate or the like. Further, by adding the epoxy acrylate monomer or the polymerizable monomer having a benzyl alcohol group to the composition and applying energy such as light or heat during the formation of the resin composition layer, adhesion to an insulating resin layer or a solder resist may be improved.

In view of the above, it is preferable that the photosensitive resin composition of the invention contains a synthetic rubber and at least one of an epoxy acrylate monomer or a polymerizable monomer having a benzyl alcohol group. In this case, the total amount of the above components (solid content) is preferably 10 to 45 parts by mass with respect to 100 parts by mass of the specific polymer (solid content).

<Solvent>

The solvent used for the photosensitive resin composition of the invention is not particularly limited as long as it dissolves the specific compound (such as the specific polymer) that is a main component of the composition. A surfactant may be added to the solvent.

Examples of the solvent that may be used include alcohol-based solvents such as methanol, ethanol, propanol, ethylene glycol, glycerin and propylene glycol monomethyl ether; acids such as acetic acid; ketone-based solvents such as acetone, methyl ethyl ketone and cyclohexanone; amide-based solvents such as formamide, dimethylacetamide and N-methylpyrrolidone; nitrile-based solvents such as acetonitrile and propionitrile; ester-based solvents such as methyl acetate and ethyl acetate; carbonate-based solvents such as dimethyl carbonate and diethyl carbonate; and the like.

Among these, when the composition includes a cyano group-containing polymerizable polymer, the solvent is preferably selected from amide-based solvents, ketone-based solvents, nitrile-based solvents and carbonate-based solvents, and specifically, acetone, dimethyl formamide, dimethyl acetamide, methyl ethyl ketone, cyclohexanone, acetonitrile, propionitrile, N-methylpyrrolidone, and dimethyl carbonate are preferred.

When the composition containing a cyano group-containing polymerizable polymer is applied by coating, a solvent having a boiling point of 50 to 150° C. is preferred from the viewpoint of handleability. The solvent may be used alone or may in combination of two or more.

In the invention, when the composition containing the specific compound is applied onto a substrate or a polymerization initiation layer, the solvent may be selected such that the solvent absorption rate of the substrate or the polymerization initiation layer is 5 to 25%. The solvent absorption rate may be determined by immersing the substrate or a base onto which the polymerization initiation layer has been formed in the solvent for 1,000 minutes, and then measuring the thickness before and after the immersion.

Further, in this case, the solvent may also be selected such that the swelling ratio of the substrate or the polymerization initiation layer is 10 to 45%. The swelling ratio may be determined by immersing the substrate or a base onto which the polymerization initiation layer has been formed in the solvent for 1,000 minutes, and then measuring the thickness before and after the immersion.

The surfactant which may be added to the solvent as necessary may be any surfactant that is soluble in the solvent. Examples of such a surfactant include anionic surfactants such as sodium n-dodecylbenzenesulfonate; cationic surfactants such as n-dodecyltrimethylammonium chloride; nonionic surfactants such as polyoxyethylene nonylphenol ether (examples of commercially available products include EMULGEN 910, trade name, manufactured by Kao Corp.), polyoxyethylene sorbitan monolaurate (examples of commercially available products include TWEEN 20, trade name, manufactured by Tokyo Chemical Industry Co., Ltd.), and polyoxyethylene lauryl ether; and the like.

If necessary, a plasticizer may also be added. The plasticizer may be selected from typical plasticizers, and it is also possible to use a plasticizer having a high boiling point such as esters of phthalic acid (dimethyl ester, diethyl ester, dibutyl ester, di-2-ethylhexyl ester, di-normal-octyl ester, diisononyl ester, dinonyl ester, diisodecyl ester, butylbenzyl ester and the like), esters of adipic acid (dioctyl ester, diisononyl ester and the like), esters of azelaic acid or sebacic acid(dibutyl ester, dioctyl ester and the like), tricresyl phosphate, tributyl acetylcitrate, epoxidized soybean oil, trioctyl trimellitate, chlorinated paraffins, dimethylacetamide and N-methylpyrrolidone, may also be used.

A polymerization inhibitor may be added to the composition containing the specific compound, if necessary. Examples of the polymerization inhibitor that may be used include hydroquinones such as hydroquinone, di-tertiary-butyl hydroquinone and 2,5-bis(1,1,3,3-tetramethylbutyl)hydroquinone; phenols such as p-methoxyphenol and phenol; benzoquinones; free radicals such as TEMPO (2,2,6,6-tetramethyl-1-piperidinyloxy free radical) and 4-hydroxy-TEMPO; phenothiazines; nitrosoamines such as N-nitrosophenylhydroxyamine and an aluminum salt thereof; and catechols.

A curing agent and/or a curing accelerator may be added to the composition in order to acceletate the curing of the polymerization initiation layer. For example, when an epoxy compound is contained in the polymerization initiation layer, examples of the curing agent and/or curing accelerator include those of polyaddition-type, such as aliphatic polyamines, alicyclic polyamines, aromatic polyamines, polyamides, acid anhydrides, phenol, phenol novolac, polymercaptans, compounds having two or more active hydrogen atoms, and those of catalyst-type, such as aliphatic tertiary amines, aromatic tertiary amines, imidazole compounds, and Lewis acid complexes.

Examples of those that initiate curing upon application of heat, light, humidity, pressure, acid, base or the like include diethylenetriamine, triethylenetetramine, tetraethylenepentamine, diethylaminopropylamine, polyamidoamine, menthenediamine, isophorone diamine, N-aminoethylpiperazine, 3,9-bis(3-aminopropyl)-2,4,8,10-tetraoxyspiro(5,5)undecane adduct, bis(4-amino-3-methylcyclohexyl)methane, bis(4-aminocyclohexyl)methane, m-xylenediamine, diaminodiphenylmethane, m-phenylenediamine, diaminodiphenylsulfone, dicyandiamide, adipic acid dihydrazide, phthalic anhydride, tetrahydrophthalic anhydride, hexahydrophthalic anhydride, methyltetrahydrophthalic anhydride, methylhexahydrophthalic anhydride, methylnadic anhydride, dodecylsuccinic anhydride, chlorendic anhydride, pyromellitic anhydride, benzophenonetetracarboxylic acid anhydride, ethylene glycol bis(anhydrotrimellitate), methylcyclohexenetetracarboxylic acid anhydride, trimellitic anhydride, polyazelaic anhydride, phenol novolac, xylylene novolac, bis-A novolac, triphenylmethane novolac, biphenyl novolac, dicyclopentadiene phenol novolac, terpene phenol novolac, polymercaptans, polysulfides, 2,4,6-tris(dimethylaminomethyl)phenol, 2,4,6-tris(dimethylaminomethyl)phenol-tri-2-ethylhexanoate, benzyldimethylamine, 2-(dimethylaminomethyl)phenol, 2-methyl imidazole, 2-ethyl-4-methylimidazole, 2-undecylimidazole, 2-heptadecylimidazole, 2-phenylimidazole, 1-benzyl-2-methylimidazole, 1-cyanoethyl-2-methyl imidazole, 2,4-diamino-6-(2-methylimidazolyl-(1))-ethyl S-triazine, BF₃ monoethylamine complex, Lewis acid complexes, organic acid hydrazides, diaminomaleonitrile, melamine derivatives, imidazole derivatives, polyamine salts, aminimide compounds, aromatic diazonium salts, diallyliodonium salts, triallylsulfonium salts, triallylselenium salts, ketimine compounds, and the like.

The curing agents and/or curing accelerator may be preferably added at an amount of up to about 0 to 50% by mass of a non-volatile component remaining after the solvent has been removed, from the viewpoint of coatability of the composition, adhesion to the substrate or the plating film, or the like. Further, the curing agent and/or curing accelerator may also be added to the polymerization initiation layer. In this case, it is preferable that the above range is satisfied by the total amount of the curing agent and/or curing accelerator that is added to the polymerization initiation layer and the amount of the same that is added to the resin composition layer.

In addition, a flame retardant (for example, a phosphorus-based flame retardant), a diluent or thixotropic agent, a pigment, a defoaming agent, a leveling agent, a coupling agent, or the like may also be added to the composition. These additives may be added to the polymerization initiation layer as necessary.

By using a composition prepared by appropriately mixing the specific compound and the aforementioned components, properties of the formed resin composition layer such as the thermal expansion coefficient, glass transition temperature, Young's modulus, Poisson's ratio, rupture stress, yield stress, thermal decomposition temperature or the like may be set at an optimal value. In particular, the rupture stress, yield stress and thermal decomposition temperature are preferably higher.

The thermal durability of the obtained resin composition layer may be measured by a temperature cycle test, a thermal aging test, a reflow test, or the like. For example, in regard to thermal decomposition, if the mass reduction after having been exposed to an environment of 200° C. for 1 hour is 20% or less, the resin composition layer may be evaluated to have sufficient thermal durability.

When the resin composition layer is formed on an arbitrary substrate by contacting the composition in the form of a liquid, the formation may be performed in an arbitrary manner. When the resin composition layer is formed by an application method, the application amount thereof (solid content) is preferably 0.1 to 10 g/m², more preferably 0.5 to 5 g/m², from the viewpoint of achieving sufficient interactability with a plating catalyst or a precursor thereof, and forming a uniform film.

<Laminate>

The photosensitive resin composition of the invention may be effectively used for the formation of a layer that receives a plating metal on an arbitrary solid. Accordingly, the laminate having a resin composition layer that is formed by applying the photosensitive resin composition of the invention on an arbitrary substrate may be effectively used for forming a plating metal having a favorable adhesiveness to the substrate.

<Method of Producing Metal Plated Material>

Next, the method of producing a metal plated material using the photosensitive resin composition of the invention is described.

The metal plated material of the invention is produced by a method including the following steps (a1) to (a3).

(a1) forming a resin composition layer from the photosensitive resin composition of the invention on a substrate

(a2) applying a plating catalyst or a precursor thereof to the resin composition layer

(a3) performing plating to the plating catalyst or the precursor thereof.

In this method, it is preferable to perform step (a1) by allowing the specific polymer in the photosensitive resin composition to directly chemically bond to the substrate. Further, step (a3) is preferably performed by electroless plating. In the following, details of each step will be described.

<Step (a1)>

Step (a1) is preferably performed by allowing the specific polymer to directly chemically bond to the substrate. In this step, the laminate of the invention having a resin composition layer on a substrate may be obtained.

It is also a preferable embodiment that step (a1) includes (a1-1) forming, on a substrate, a polymerization initiation layer that contains a polymerization initiator or a functional group capable of initiating polymerization, and (a1-2) forming, on the polymerization initiation layer, a resin composition layer from the photosensitive composition containing the specific polymer that directly chemically bonds to the polymerization initiation layer.

Step (a1-2) is preferably performed by contacting the specific polymer to the polymerization initiation layer, and then applying energy to allow the specific polymer to directly chemically bond to the entire surface of the substrate (entire surface of the polymerization initiation layer).

(Surface Graft Polymerization)

The formation of the resin composition layer on the substrate is typically performed by a technique called surface graft polymerization. The graft polymerization is a technique of applying an active species onto a polymer chain to allow another kind of monomer that initiates polymerization by the active species to polymerize, thereby synthesizing a graft polymer. When the polymer that imparts the active species forms a surface of a solid, this technique is called surface graft polymerization.

The surface graft polymerization that is applied to the invention may be any method known by documents. For example, a photo graft polymerization method and a plasma-irradiation graft polymerization method are described as a surface graft polymerization method on page 135 of Shin Koubunshi Jikken-gaku 10, edited by Society of Polymer Science, 1994, published by Kyoritsu Shuppan Co., Ltd. (ISBN: 9784320043350). Further, a radiation graft polymerization method using gamma rays or electron beams is described on pages 203 and 695 of Kyuchaku Gijutsu Binran, edited by Takeuchi, February 1992, published by NTS (ISBN4-900830-34-8).

Specific examples of the photo graft polymerization method that may be applied to the invention are described in J-P-A No. 63-92658, J-P-A No. 10-296895 and JP-A No. 11-119413.

The formation of the resin composition layer may be performed by other methods than the surface graft polymerization, for example, by a method of applying to a distol end of polymer chain a reactive functional group such as a trialkoxysilyl group, an isocyanate group, an amino group, a hydroxyl group or a carboxyl group, and then bonding the same to a functional group that is present at a surface of the substrate by coupling reaction.

Among these methods, a photo graft polymerization method is preferable in view of generating more graft polymer, and a method of forming a resin composition layer by a photo graft polymerization method using UV light is particularly preferable.

<Substrate>

The substrate used in the invention is not particularly limited as long as it has a surface onto which a polymer having a functional group that interacts with a plating catalyst or a precursor thereof can be directly chemically bonded. The substrate itself may have such a surface characteristics, or an intermediate layer formed on a base material to form the substrate (such as a polymerization initiation layer to be described later) may have the same.

(Base Material and Substrate)

The base material used in the invention is preferably a dimensionally stable plate-shaped object, and examples thereof include a sheet of paper, a sheet of paper laminated with a plastic (for example, polyethylene, polypropylene, polystyrene and the like), a plate of a metal (for example, aluminum, zinc, copper and the like), a film of a plastic (for example, cellulose diacetate, cellulose triacetate, cellulose propionate, cellulose butyrate, cellulose acetate, nitrocellulose, polyethylene terephthalate, polyethylene, polystyrene, polypropylene, polycarbonate, polyvinylacetal, polyimide, epoxy resin, bismaleimide resin, polyphenylene oxide, liquid crystal polymer, polytetrafluoroethylene and the like), a film of paper or plastic onto which a metal as mentioned above is laminated or deposited, and the like. The base material to be used in the invention is preferably made of an epoxy resin or a polyimide resin.

When a surface of the base material has a function of reacting with the monomer used in the formation of the resin composition layer to form a chemical bond, the base material itself may be used as the substrate.

The base material containing a polyimide having a polymerization initiation site in the skeleton thereof, as described in paragraphs [0028] to [0088] of JP-A No. 2005-281350, may also be used for the substrate.

The metal pattern material obtained by the method of producing a metal pattern material of the invention may be applied to a semiconductor package, various kinds of electrical wiring boards, and the like. When the metal pattern material is used in such applications, it is preferable to use a substrate including an insulating resin, as shown below. Specifically, it is preferable to use a substrate formed from an insulating resin, or a substrate having a layer formed from an insulating resin on a base material.

The substrate formed from an insulating resin or the layer formed from an insulating resin may be formed using a known insulating resin composition. The insulating resin composition may include an additive of various kinds in combination with the resin as a main component, according to purposes. For example, a polyfunctional acrylate monomer may be added for the purpose of increasing the strength of the insulating layer, or inorganic or organic particles may be added for the purpose of increasing the strength of the insulating layer and improving the electrical properties thereof.

Here, the “insulating resin” according to the invention means a resin having an insulating property that is tolerable for use in known insulating films or insulating layers. Therefore, the resin does not have to be completely insulating, as long as it has an insulating property that satisfies the requirements according to purposes.

The insulating resin may be a thermosetting resin, a thermoplastic resin, or a mixture thereof. Specifically, examples of the thermosetting resin include epoxy resins, phenolic resins, polyimide resins, polyester resins, bismaleimide resins, polyolefin-based resins, isocyanate-based resins, and the like.

Examples of the epoxy resins include cresol novolac type epoxy resins, bisphenol A type epoxy resins, bisphenol F type epoxy resins, phenol novolac type epoxy resins, alkylphenol novolac type epoxy resins, biphenol F type epoxy resins, naphthalene type epoxy resins, dicyclopentadiene type epoxy resins, epoxides of a condensate formed from a phenol and an aromatic aldehyde having a phenolic hydroxyl group, triglycidyl isocyanurate, alicyclic epoxy resins, and the like. These may be used alone, or may be used in combination of two or more species. By including the insulating resin as mentioned above, excellent heat resistance or the like may be obtained.

Examples of the polyolefin-based resins include polyethylene, polystyrene, polypropylene, polyisobutylene, polybutadiene, polyisoprene, cycloolefin-based resins, copolymers of these resins, and the like.

Examples of the thermoplastic resins include phenoxy resins, polyether sulfone, polysulfone, polyphenylene sulfone, polyphenylene sulfide, polyphenyl ether, polyether imide, and the like.

Other thermoplastic resins include 1,2-bis(vinylphenylene)ethane resin, or a modified resin obtained from the 1,2-bis(vinylphenylene)ethane resin and a polyphenylene ether resin (described in Satoru Amou et al., Journal of Applied Polymer Science, Vol. 92, pp. 1252-1258 (2004)), liquid crystal polymers (for example, VECSTAR, trade name, manufactured by Kuraray Co., Ltd.), fluororesins (PTFE), and the like.

The thermoplastic resin and the thermosetting resin may be used in combination for the purpose of compensating the defects of each resin to achieve better effects. For example, since a thermoplastic resin such as polyphenylene ether (PPE) has low resistance to heat, alloying with a thermosetting resin or the like may be carried out, such as alloying of PPE with epoxy or triallyl isocyanate, or alloying of a PPE resin to which a polymerizable functional group has been introduced with another thermosetting resin. Further, a cyanate ester is a resin that exhibits the most excellent dielectric properties among the thermosetting resins, but is hardly used alone and mainly used as a modified resin of epoxy resins, maleimide resins, thermoplastic resins and the like. Details of these resins are described in “Electronic Technology” No. 2002/9, p. 35. Furthermore, a mixture containing an epoxy resin and/or a phenolic resin as a thermosetting resin, and a phenoxy resin and/or polyethersulfone (PES) as a thermoplastic resin, may also be used for the purpose of improving dielectric properties.

The insulating resin composition may include a compound containing a polymerizable double bond in order to promote crosslinking reaction. Specific examples of the compound include an acrylate or methacrylate compound, particularly preferably a polyfunctional acrylate or methacrylate compound. Other applicable compounds containing a polymerizable double bond include those obtained by subjecting a part of a thermosetting resin or a thermoplastic resin (for example, an epoxy resin, a phenolic resin, a polyimide resin, a polyolefin resin, or a fluororesin) to a (meth)acrylation reaction using methacrylic acid, acrylic acid or the like.

A composite of a resin and other component may also be used as the insulating resin composition for the purpose of reinforcing the properties of a resin film, such as mechanical strength, heat resistance, weather resistance, flame retardancy, water resistance or electrical properties. Examples of the material that may be used for producing a composite include paper, glass fiber, silica particles, phenolic resins, polyimide resins, bismaleimide triazine resins, fluororesins, polyphenylene oxide resins, or the like.

Further, the insulating resin composition may be compounded with, if necessary, one or more kind of filler for use in general resin materials for wiring boards. Examples of the filler include inorganic fillers such as silica, alumina, clay, talc, aluminum hydroxide and calcium carbonate, and organic fillers such as cured epoxy resin, crosslinked benzoguanamine resin and crosslinked acrylic polymer. Among them, silica is preferably used as the filler.

The insulating resin composition may also include one or more additive of various kinds as necessary, such as a colorant, a flame retardant, a tackifier, a silane coupling agent, an antioxidant, an ultraviolet absorbent, and the like.

When these materials are added to the insulating resin composition, the total amount of the same is preferably 1 to 200% by mass, more preferably 10 to 80% by mass, with respect to the amount of the resin. If the above amount is less than 1% by mass, effects of reinforcing the aforementioned properties may not be achieved, while if the above amount is more than 200% by mass, properties that are inherent to the resin, such as strength, may deteriorate.

It is preferable that the substrate for use in the aforementioned applications is formed from an insulating resin having a dielectric constant (relative dielectric constant) at 1 GHz of 3.5 or less, or has a layer formed from the insulating resin on a base material. Further, it is preferable that the substrate is formed from an insulating resin having a dielectric loss tangent at 1 GHz of 0.01 or less, or has the layer formed from the insulating resin on a base material.

The dielectric constant and the dielectric loss tangent of an insulating resin may be measured by standard methods. For example, the properties may be measured by using a cavity resonator perturbation method (for example, a ∈r tan δ measuring device for a ultra-thin sheet, manufactured by Keycom Corp.).

As mentioned above, it is also advantageous to select the insulating resin material from the viewpoint of dielectric constant or dielectric loss tangent. Examples of the insulating resin having a dielectric constant of 3.5 or less and a dielectric loss tangent of 0.01 or less include liquid crystal polymers, polyimide resins, fluororesins, polyphenylene ether resins, cyanate ester resins, and bis(bisphenylene)ethane resins, and modified resins of these resins.

The substrate for use in the invention preferably has a surface roughness of 500 nm or less, more preferably 100 nm or less, even more preferably 50 nm or less, and most preferably 20 nm or less, in view of applications to semiconductor packages, various electrical wiring boards, and the like. The surface roughness of the substrate (when an intermediate layer or a polymerization initiation layer is provided, the surface roughness of that layer) is preferably smaller, since the electric loss at the time of transmitting electricity at high frequency may be smaller when the metal pattern material is used for wiring lines or the like.

When the substrate has a shape of a plate such as a resin film (plastic film), a resin composition layer may be formed on both sides of the substrate by conducting step (a1) to both sides thereof. Further, by conducting the later-described steps (a2) and (a3) to the both sides of the substrate, a metal-plated material having a metal film on both sides thereof may be obtained.

In the invention, when a surface graft polymerization method in which a graft polymer is generated starting from an active species that has been applied to the surface of the substrate is employed, the substrate preferably has a polymerization initiation layer containing a polymerization initiator or a functional group capable of initiating polymerization. By using the substrate having the polymerization initiation layer, active sites may be efficiently generated, thereby generating more graft polymer.

Hereinafter, the polymerization initiator layer according to the invention will be described. When the base material is a plate-shaped object, the polymerization layer may be formed on both sides thereof

(Polymerization Initiation Layer)

Examples of the polymerization initiation layer according to the invention include a layer containing a polymer compound and a polymerization initiator; a layer containing a polymerizable compound and a polymerization initiator; and a layer containing a functional group capable of initiating polymerization.

The polymerization initiation layer according to the invention may be formed by preparing a composition by dissolving necessary components in a solvent capable of dissolving them, applying the same onto the surface of a base material by coating or the like, and curing the formed film by applying heat or light.

(a) Polymerizable Compound

The polymerizable compound that may be used in the polymerization initiation layer is not particularly limited as long as it may achieve favorable adhesion to the base material and generate a surface graft polymer by applying energy such as actinic rays. The polymerizable compound used in the invention may be a polyfunctional monomer or the like, but is particularly preferably a hydrophobic polymer having a polymerizable group in the molecule.

Specific examples of the hydrophobic polymer include diene-based homopolymers such as polybutadiene, polyisoprene and polypentadiene, homopolymers of an allyl group-containing monomer such as allyl (meth)acrylate and 2-allyloxyethyl methacrylate;

bicomponent or multicomponent copolymers of styrene, (meth)acrylic acid ester, (meth)acrylonitrile and the like, containing a diene-based monomer such as butadiene, isoprene or pentadiene, or an allyl group-containing monomer as a constituent unit; and

linear polymers or terpolymers having a carbon-carbon double bond in the molecule such as unsaturated polyesters, unsaturated polyepoxides, unsaturated polyamides, unsaturated polyacrylics, and high density polyethylene.

In the present specification, when referring to both or either one of “acryl” and “methacryl”, the term “(meth)acryl” is used sometimes.

The content of the polymerizable compound is preferably in the range of 0 to 100% by mass, and particularly preferably 10 to 80% by mass, in terms of the solid content in the polymerization initiation layer.

(b) Polymerization Initiator

The polymerization initiation layer may contain a polymerization initiator in order to express a polymerization initiation ability upon application of energy. The polymerization initiator used here may be appropriately selected from known ones, such as those described in paragraphs [0043] to [0044] of JP-A No. 2007-154306, according to purposes. Among them, a photo-polymerization initiator is favorably used since photo-polymerization is favorable from the viewpoint of production suitability.

The photo-polymerization initiator is not particularly limited as long as it is active to actinic rays to be applied and is capable of surface graft polymerization, and examples thereof include a radical polymerization initiator, an anionic polymerization initiator, a cationic polymerization initiator, or the like. From the viewpoint of reactivity, a radical polymerization initiator is preferable.

The content of the polymerization initiator in the polymerization initiation layer is preferably 0.1 to 70 mass %, more preferably 1 to 40 mass %, in terms of solid content.

The polymerization initiator may be a photo-cationic polymerization initiator or a photo-radical polymerization initiator.

Photo-Cationic Polymerization Initiator

The photo-cationic polymerization initiator is a compound that initiates cationic polymerization by generating acid when irradiated with actinic rays or radiation rays, and known compounds or a mixture thereof may be appropriately selected and used.

Examples of the photo-cationic polymerization initiator that may be used in the invention include those described in paragraphs [0043] to [0092] of JP-A No. 2006-274052.

Photo-Radical Polymerization Initiator

The photo-radical polymerization initiator may be a low-molecular compound or a high-molecular compound.

Examples of the low-molecular photo-radical polymerization initiator include known radical generators, such as acetophenones, hydroxyalkylphenones, benzophenones, Michler's ketone, benzoyl benzoate, benzoins, alfa-acyloxim ester, tetramethyl thiuram monosulfide, trichloromethyl triazine, and thioxanthone. Further, a sulfonium salt or an iodonium salt, which is typically used as a photo-acid generator but also functions as a radical generator when irradiated with light, may also be used in the invention.

Examples of the high-molecular photo-radical polymerization initiator include a polymer compound having an active carbonyl group, trichloromethyl triazine, or thioxanthone in a side chain, such as those described in JP-A No. 9-77891, JP-A No. 10-45927, paragraphs [0094] to [0107] of JP-A No. 2007-146103, JP-A No. 2006-264706, Photochemistry & Photobiology, Vol. 5, page 46 (1999), and the like.

The photo-radical polymerization initiator is preferably a high-molecular photo-radical polymerization initiator, from the viewpoint of graft polymerizability. The weight average molecular weight of the high-molecular photo-radical polymerization initiator is preferably 10,000 or more, more preferably 30,000 or more. From the viewpoint of solubility, the weight average molecular weight of the high-molecular photo-radical polymerization initiator is preferably not more than 100,000.

When an epoxy resin is used as a polymerizable compound, the epoxy resin itself may be used as a high-molecular photo-radical polymerization initiator. Examples of this type of high-molecular photo-radical polymerization initiator include those described in paragraphs [0094] to [0107] of JP-A No. 2007-146103 or the following Compounds (26) to (30). In the following, x and y represent a mole fraction and x+y=100 (either x and y are not 100).

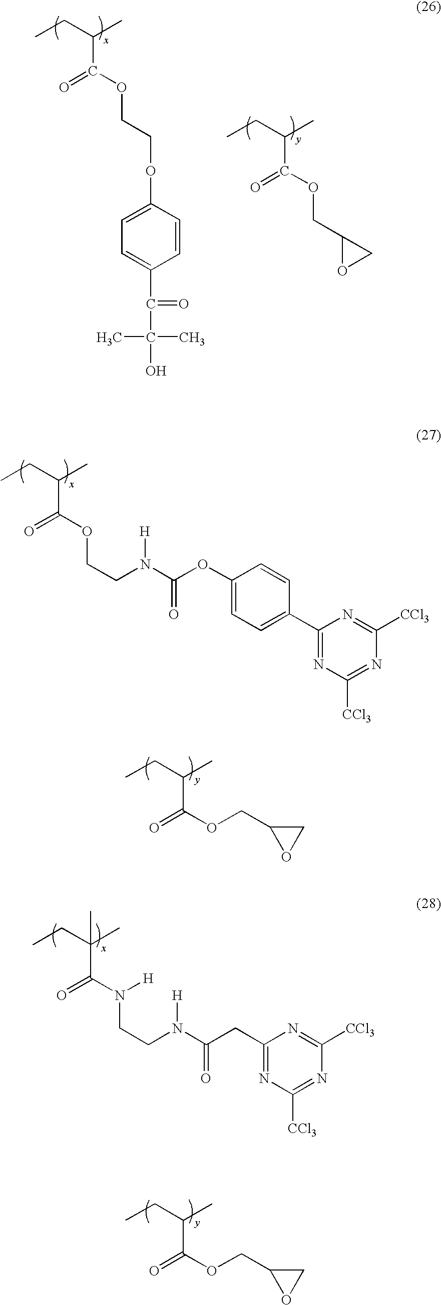

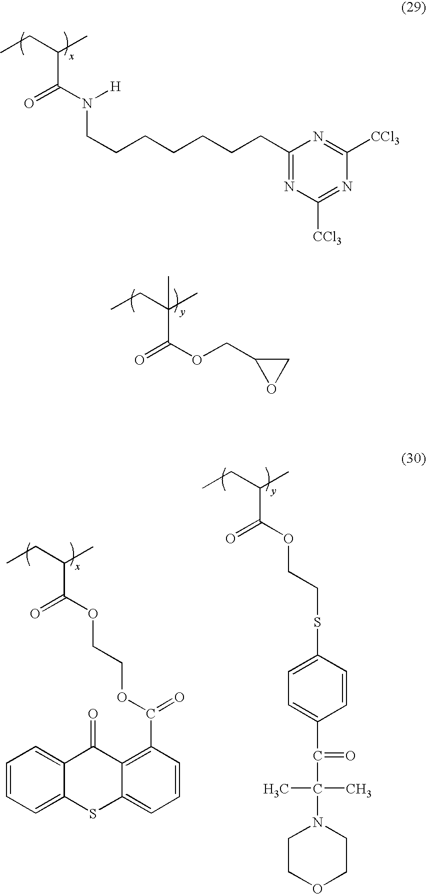

When the photo-radical polymerization initiator is used, the content thereof with respect to the total solid content of the composition is preferably 0.1 to 50 mass %, more preferably 1.0 to 30.0 mass %, from the viewpoints of graft polymerizability, suppressing reduction in adhesive strength due to the graft polymerizability, suppressing reduction in the glass transition temperature of the cured product, and avoiding problems in thermal or electric characteristics such as increase in dielectric constant of the cured product, or the like.

(Solvent)

The solvent used for the application of polymerizable compound or polymerization initiator is not particularly limited as long as it can dissolve the component. From the viewpoints of ease of drying or handling, solvents having a boiling point that is not very high are preferable, and may be selected from those having a boiling point of 40 to 150° C.

Specific examples of the solvent include those described in paragraph [0045] of JP-A No. 2007-154306. The solvent may be used alone or in combination of two or more. The appropriate concentration of the solvent in the composition is 2 to 50 mass %, in terms of solid content.

When a polymerization initiation layer is formed on a substrate, the application amount thereof after drying by mass is preferably 0.1 to 20 g/m², more preferably 1 to 15 g/m², in view of achieving a sufficient polymerization initiation ability or suppressing exfoliation of the layer while maintaining its film property.

When the polymerization initiation layer is formed by depositing the composition for polymerization initiation layer on a base material and then removing the solvent to form a film, it is preferable to cure the film by applying heat and/or light. It is particularly preferable to perform pre-curing of the layer after drying the same by heating, since if the curing of the polymerizable compound is promoted to some extent beforehand, it may effectively suppress exfoliation of the polymerization initiation layer after the completion of graft polymerization.

The temperature and time for the heating may be appropriately selected such that the solvent may be sufficiently dried, but the drying temperature is preferably 100° C. or less, more preferably 40 to 80° C., and the drying time is preferably 30 minutes or less, more preferably 10 minutes or less, from the viewpoint of production suitability.

The light source used for the light irradiation that may be optionally performed after the heating for drying may be the light source that may be used in a graft polymerization reaction to be described later. In order not to hinder the formation of bonding of an active site to a graft chain in the polymerization initiation layer that is performed by applying energy, it is preferable that the light irradiation at the pre-curing is performed such that the radical polymerization of polymerizable compound is not completed. The time for irradiation may vary depending on the intensity of the light source, but is typically 30 minutes or less. The pre-curing may be performed, for example, such that the residual ratio of the film after washing with a solvent is 10% or less, and the residual ratio of the polymerization initiator after the pre-curing is 1% or more.

(Generation of Graft Polymer)

The generation of a graft polymer in step (a1) may be performed, as mentioned above, by a method of using a coupling reaction of a functional group that is present on the surface of the substrate and a reactive functional group at a distol end or a side chain of the polymer compound, or a photo-graft polymerization method.

In the invention, it is preferable to prepare a substrate formed from a base material and a polymerization initiation layer formed on the base material, and then form a resin composition layer in which the specific compound is directly chemically bonded to the polymerization initiation layer.

In a further preferable embodiment, the polymer is directly chemically bonded to the entire surface of the substrate (entire surface of the polymerization initiation layer) by applying energy after contacting the specific compound to the polymerization initiation layer. Namely, the specific polymer is directly bonded by means of an active species that is generated on the surface of the polymerization initiation layer, by contacting the composition containing the specific polymer.

(Adhesion Aiding Layer)

In the invention, an adhesion aiding layer may be provided in place of the polymerization initiation layer. For example, when the substrate as described later is formed from a known insulating resin that has been used as a material for a multilayer laminate, build-up substrate or flexible substrate, an insulating resin composition is preferably used for the formation of the adhesion aiding layer from the viewpoint of adhesiveness to the substrate.

The following are explanation of an embodiment of the adhesion aiding layer that is formed from an insulating resin composition that is suitable when the substrate is formed from an insulating resin.

The insulating resin composition that is used for forming the adhesion aiding layer may include the same electrically insulating resin used for the substrate or may not, but it is preferable to use a resin having similar thermal properties to that of the resin used for the substrate, such as glass transition temperature, elasticity or linear expansion coefficient. Specifically, for example, it is preferable to use the same resin as that used for the substrate.

Further, the insulating resin composition may include inorganic or organic particles for the purpose of increasing the strength of adhesion aiding layer or improving the electric characteristics.

The insulating resin according to the invention refers to a resin having an insulating property that is tolerable for use in known insulating films. Therefore, a resin that is not completely insulating but has an insulating property that is satisfactory for an intended use may be applied to the invention. The insulating resin may be a thermosetting resin, a thermoplastic resin or a mixture thereof.

Specific examples of the thermosetting resin include an epoxy resin, a phenol resin, a polyimide resin, a polyester resin, a bismaleimide resin, a polyolefin resin, and an isocyanate resin.

Specific examples of the thermoplastic resin include a phenoxy resin, polyethersulfone, polysulfone, polyphenylenesulfone, polyphenylenesulfide, polyphenylether, and polyetherimide.

Each of the thermosetting resin and the thermoplastic resin may be used alone or in combination of two or more. Mixing two or more resins may be effective to exhibit superior effects by compensating the shortcomings of each other.

The insulating resin used for the adhesion aiding layer may be a resin having a skeleton that generates an active cite capable of interacting with a plating catalyst-receptive photosensitive resin composition. One example thereof is polyimide resins having a polymerization initiation site in the skeleton, which are described in paragraphs [0018] to [0078] of JP-A No. 2005-307140.

Further, the adhesion aiding layer may include a compound having a polymerizable double bond in order to promote the crosslinking in the layer. Specific examples of the compound include an acrylate or methacrylate compound, particularly preferably a polyfunctional acrylate or methacrylate compound. Other applicable compounds having a polymerizable double bond include those obtained by acrylating or methacrylating a part of a thermosetting resin or a thermoplastic resin (for example, an epoxy resin, a phenol resin, a polyimide resin, a polyolefin resin, or a fluororesin), using methacrylic acid, acrylic acid or the like.

The adhesion aiding layer may include a compound of various kinds according to purposes to such an extent that the effects of the invention is not impaired.

Specific examples thereof include a compound that can lessen the stress such as a rubber or SBR latex, and a compound that can improve the film property such as a binder, a plasticizer, a surfactant, or a viscosity adjuster.

A composite of a resin and other component may also be used for the adhesion aiding layer, for the purpose of reinforcing the properties of a resin film, such as mechanical strength, heat resistance, weather resistance, flame retardancy, water resistance or electrical properties. Examples of the material that may be used for producing a composite include paper, glass fiber, silica particles, phenol resins, polyimide resins, bismaleimide triazine resins, fluororesins, polyphenylene oxide resins, or the like.

Further, the adhesion aiding layer may include, as necessary, one or more kinds of filler that is used in typical resin materials for wiring boards. Examples of the filler include inorganic fillers such as silica, alumina, clay, talc, aluminum hydroxide and calcium carbonate, and organic fillers such as cured epoxy resin, crosslinked benzoguanamine resin and crosslinked acrylic polymer.

The insulating resin composition may also include one or more kinds of additive as necessary, such as a colorant, a flame retardant, a tackifier, a silane coupling agent, an antioxidant, an ultraviolet absorbent, and the like.

When these materials are added to the insulating resin composition, the total amount of the same is preferably 0 to 200% by mass, more preferably 0 to 80% by mass, with respect to the amount of the resin as a main component. If the substrate that contacts the adhesion aiding layer has the same or similar physical values with respect to heat or electricity, these additives may not necessarily be included in the composition. If the above amount is more than 200% by mass, properties that are inherent to the resin, such as strength, may deteriorate.

The adhesion aiding layer preferably includes, as mentioned above, an active species (compound) that generates an active site capable of interacting with the photosensitive composition. The active cite is generated upon application of energy, preferably light (such as ultraviolet rays, visible rays or X rays), plasma (such as oxygen, nitrogen, carbon dioxide or argon), heat, electricity, or the like. Further, it is also possible to generate an active sited by chemically decomposing the surface of the adhesion aiding layer.

Examples of the active species include the aforementioned thermal polymerization initiator or photo polymerization initiator that may be included in the polymerization initiation layer, such as those described in paragraphs [0043] and [0044] of JP-A No. 2007-154306. The amount of polymerization initiator included in the adhesion aiding layer (solid content) is preferably 0.1 to 50 mass %, more preferably 1.0 to 30 mass %. In this way, the adhesion aiding layer may have similar functions to those of the polymerization initiation layer.

The thickness of the adhesion aiding layer is typically 0.1 to 10 μm, more preferably 0.2 to 5 μm.

The solvent used for the application of the adhesion aiding layer is not particularly limited as long as it can dissolve the components of the composition, but is preferably a solvent having a boiling point that is not very high, such as those having a boiling point of about 40 to 150° C.

Specific examples of the solvent that may be used include cyclohexanone or methyl ethyl ketone described in paragraph [0045] of JP-A No. 2007-154306. The solvent may be used alone or in combination of two or more kinds. The appropriate solid content concentration of the composition is 2 to 50 mass %.

The application amount of the adhesive aiding layer on the substrate after drying is preferably 0.1 to 20 g/m², more preferably 0.1 to 15 g/m², further preferably 0.1 to 2 g/m², from the viewpoint of achieving sufficient polymerization initiation ability and suppressing exfoliation of the film while maintaining the film property.

In the invention, as mentioned above, it is preferable to perform pre-curing by applying heat and/or light at the time of depositing the composition for adhesion aiding layer onto the substrate by coating or the like, and removing the solvent to form a film. It is particularly preferable to perform the pre-curing by irradiating the layer with light after drying the layer by heating, since if the curing of the polymerizable compound is promoted to some extent beforehand, exfoliation of the adhesion aiding layer after the completion of graft polymerization may be effectively suppressed.

The temperature and time for the heating may be appropriately selected such that the solvent may be sufficiently dried, but the drying temperature is preferably 100° C. or less, more preferably 40 to 80° C., and the drying time is preferably 30 minutes or less, more preferably 10 minutes or less, from the viewpoint of production suitability.

The adhesion aiding layer may be formed on a surface of the substrate (such as a resin film) on which the resin composition layer is to be formed, by a known technique such as coating, transferring or printing.

When the adhesion aiding layer is formed by a transfer method, the formation may be performed by preparing a laminate including a layer formed from a photosensitive resin composition containing the specific compound and the adhesion aiding layer, and then transferring the laminate to the substrate by a lamination method.

The adhesion aiding layer may be subjected to a curing process after being formed on the substrate. Examples of the energy to be applied include light, heat, pressure, electron beam or the like, but heat or light is typically used in this embodiment. The heat is preferably applied at 100 to 300° C. for 5 to 120 minutes. The conditions for the heat-curing depend on the type of material for the substrate (resin film) and a resin composition that forms the adhesion aiding layer or the curing temperature of the material, but is preferably selected from the range of 120 to 220° C. and 20 to 120 minutes.

The curing process may be performed immediately after the formation of adhesion aiding layer. If a pre-curing treatment of about 5 to 10 minutes is performed after the formation of adhesion aiding layer, the curing process may be performed after all processes that are performed after the formation of adhesion aiding layer.

The surface of the adhesion aiding layer may be roughened by a wet and/or dry method for the purpose of improving the adhesiveness to the resin composition layer that is to be formed on the adhesion aiding layer. The dry roughening methods include mechanical polishing such as buffing and sandblasting, and plasma etching. The wet roughening methods include a chemical treatment using an oxidant such as permanganate, dichromate, ozone, hydrogen peroxide, sulfuric acid and nitric acid, strong acid, or a resin-swelling solvent.

When the substrate has a layer formed from an insulating resin on a base material, the insulating resin layer is preferably an insulating polymerization initiation layer by including a known polymerization initiator. The polymerization initiator that may be used in the layer is not particularly limited, and examples thereof include the aforementioned heat polymerization initiator or photo polymerization initiator (such as a radical polymerization initiator, an anionic polymerization initiator and a cationic polymerization initiator), a polymer compound having an active carbonyl group in a side chain as described in JP-A No. 9-77891 and JP-A No. 10-45927, and a polymer having a functional group capable of initiating polymerization or a crosslinkable group in a side chain (polymerization initiation polymer).

The amount of the polymerization initiator in the insulating layer (sold content) is preferably about 0.1 to 50 mass %, more preferably about 1.0 to 30.0 mass %.

In the invention, it is possible to provide a polymerization initiation layer or an adhesion aiding layer as a primer layer on which the resin composition layer is to be formed, preferably an adhesion aiding layer.

The composition containing the specific compound may be contacted to the substrate on which the polymerization initiation layer or adhesion aiding layer has been formed by immersing the substrate into the composition containing the specific compound. However, from the viewpoint of handleability or production efficiency, it is preferable to form a layer from the composition containing the specific compound on the surface of the substrate (polymerization initiation layer or adhesion aiding layer) by an application method.

Further, when a layer of the composition is formed on both sides of the substrate (such as a resin film), as mentioned in step (a1″) in the third method of producing a metal plated material, the layer is preferably formed by an application method in view of ease of forming two layers on both sides of the substrate at the same time.

When contacting the composition containing the specific compound to the surface of the substrate, the application amount thereof (solid content) is preferably 0.1 to 10 g/m², more preferably 0.5 to 5 g/m², from the viewpoint of achieving sufficient interaction with a plating catalyst or a precursor thereof.

When a layer containing the specific compound is formed by applying the composition containing the specific polymer onto the substrate and drying the same, the substrate onto which the composition has been applied may be left to stand at 20 to 40° C. for 0.5 to 2 hours prior to the drying, in order to remove the residual solvent.

(Application of Energy)

The application of energy to the surface of the substrate may be performed by applying radiation rays such as heat or light, such as light irradiation with a UV lamp or visible light, or heating with a hot plate. Examples of the light source include a mercury lamp, a metal halide lamp, a xenon lamp, a chemical lamp, and a carbon arc lamp. Examples of the radiation rays include electron beams, X-rays, ion beams, and far-infrared rays. Further, g-line rays, i-line rays, deep-UV light, high-density energy beams (laser beams) are also applicable.

Specific embodiments of energy application that are typically-used include direct image-wise recording using a thermal recording head or the like, scan exposure using infrared laser beam, high-light intensity flash exposure using a xenon discharge lamp or the like, or exposure with an infrared lamp.

The time for energy application may vary depending on the intended amount of graft polymer generation or the type of light source, but is typically from 10 seconds to 5 hours.

When the application of energy is performed by exposure, the exposure power is preferably 10 to 5,000 mJ/cm², more preferably 50 to 3,000 mJ/cm², from the viewpoints of readily promoting the graft polymerization and suppressing the decomposition of generated graft polymer.

When the specific compound is a polymer having an average molecular weight of 20,000 or more and a polymerization degree of 200-mer or more, graft polymerization may readily progress even when exposure is performed at low energy. Therefore, the decomposition of generated graft polymer may be further suppressed.

In step (a1) as mentioned above, a resin composition layer (graft resin composition layer) formed from a graft polymer having an interactive group may be formed on the substrate.

The obtained resin composition layer may be subjected to washing with a highly alkalic solution, provided that not more than 50% of the polymerizable group site decomposes after placing the layer in an alkali solution of pH 12 and stirring it for 1 hour, for example.

<Step (a1′)>

In step (a1′) of the method of producing a metal plated material of the invention, a polymer having a cyano group is used as the specific compound, and a resin composition layer in which the polymer having a cyano group is directly chemically bonded to the substrate is formed.

Step (a1′) may be performed in a similar manner to step (a1), except that a compound having a polymerizable group and a cyano group is used as the specific polymer, and preferable embodiments are also the same.

In step (a1′), a resin composition layer (graft resin composition layer) of a graft polymer having a cyano group may be formed on the substrate.

The polymer that forms the resin composition layer in this step has a cyano group as a functional group that interacts with a plating catalyst or a precursor thereof. The cyano group has, as mentioned above, a high degree of polarity and a high adsorption capability for a plating catalyst or the like, but does not have a high water absorption capability or hydrophilicity such as that of a dissociative polar group (hydrophilic group). Therefore, the resin composition layer formed from a graft polymer having a cyano group exhibits a low water absorption capability and is highly hydrophobic.

<Step (a2)>

In step (a2), a plating catalyst or a precursor thereof is applied to the resin composition layer formed in step (a1) or step (a1′). In this step, the interactive group (such as a cyano group) of graft polymer that forms the resin composition layer attracts (adsorbs) the applied plating catalyst or the precursor thereof, according to the function of the group.

Examples of the plating catalyst or the precursor thereof include those that function as a catalyst or as an electrode for plating in the subsequent step (a3) that will be described later. Therefore, the type of the plating catalyst or the precursor thereof is selected according to the type of plating performed in step (a3).

Further, the plating catalyst or the precursor thereof used in this step is preferably an electroless plating catalyst or a precursor thereof.

(Electroless Plating Catalyst)

In the invention, the electroless plating catalyst may be any compound as long as it serves as an active core during performing electroless plating. Examples thereof include metals having a catalytic ability for a self-catalytic reduction reaction (metals capable of electroless plating and having an ionization tendency that is not more than that of Ni), and specific examples include Pd, Ag, Cu, Ni, Al, Fe, Co and the like. Among them, those capable of multidentate coordination are preferred. From the viewpoints of the number of types of a functional group capable of coordination and superiority in the catalytic ability, Pd is particularly preferred.

This electroless plating catalyst may be used in the form of a metal colloid. In general, a metal colloid may be produced by reducing metal ions in a solution containing a charged surfactant or a charged protective agent. The electrical charge of the metal colloid may be controlled by the surfactant or protective agent used herein.

(Electroless Plating Catalyst Precursor)

The electroless plating catalyst precursor used in this step is not particularly limited and may be any compound as long as it may serve as an electroless plating catalyst by a chemical reaction. In general, metal ions of the metals mentioned above as the electroless plating catalyst are used. A metal ion that serves as an electroless plating catalyst precursor becomes a zero-valent metal that serves as an electroless plating catalyst through a reduction reaction. The metal ion as an electroless plating catalyst precursor may be converted to a zero-valent metal to obtain an electroless plating catalyst by performing a separate reduction reaction, after being applied to the resin composition layer and prior to immersing in an electroless plating bath, or may be converted to a metal (electroless plating catalyst) while being immersed in an electroless plating bath by means of a reducing agent contained in the electroless plating bath.

Practically, the metal ion as an electroless plating catalyst precursor is provided onto the resin composition layer by using a metal salt. The metal salt to be used is not particularly limited as long as it can be dissolved in an appropriate solvent to dissociate into a metal ion and a base (anion). Specific examples thereof include M(NO₃)ₙ, MCln, M_{2/n}(SO₄), M_{3/n}(PO₄) and M(OAc)n (where M represents an n-valent metal atom and Ac represents an acetyl group). The resultant of dissociation of the above-mentioned metal salts may be suitably used as the metal ion. Specific examples of the metal ion include an Ag ion, a Cu ion, an Al ion, a Ni ion, a Co ion, a Fe ion, and a Pd ion. Among them, those capable of multidentate coordination are preferred. From the viewpoints of the number of types of a functional group capable of coordination and the catalytic ability, a Pd ion is particularly preferred.

(Other Catalysts)

When electroplating is performed to the resin composition layer without performing electroless plating in the subsequent step (a3), a zero-valent metal may be used as the catalyst. Examples of the zero-valent metal include Pd, Ag, Cu, Ni, Al, Fe and Co. Among them, those capable of multidentate coordination are preferred. From the viewpoints of the adsorbability (attachability) to the interactive group (such as a cyano group) and the superiority in catalytic ability, Pd, Ag and Cu are particularly preferred.

One example of the method of providing a metal as an electroless plating catalyst or a metal ion as an electroless plating catalyst precursor to the resin composition layer is that in which a dispersion containing a metal dispersed in an appropriate dispersion solvent, or a solution containing a dissociated metal ion obtained by dissolving a metal salt in an appropriate solvent, is applied onto the resin composition layer, or the substrate with the resin composition layer formed thereon is immersed in the dispersion or the solution.

Further, when a surface graft polymerization method is performed in step (a1) or step (a1′), an electroless plating catalyst or a precursor thereof may be added to the composition containing the specific compound (or cyano group-containing polymerizable polymer) that contacts the substrate. In this way, it is possible to form a resin composition layer that contains an interactive group (such as cyano group), is directly chemically bonded to the substrate, and contains a plating catalyst or a precursor thereof. By employing this method, it is possible to perform step (a1) or step (a1′) and step (a2) in a single process.

When the resin composition layer is formed on both sides of the substrate (such as a resin film) in step (a1″) in the third method of producing a metal plated material in the invention, step (a2) is preferably performed by the aforementioned immersion method so as to contact an electroless plating catalyst or a precursor thereof to the resin composition layer of both sides at one time.

(Organic Solvent)

The solution containing a plating catalyst or a precursor thereof (plating catalyst solution) may contain an organic solvent. In this way, the plating catalyst or the precursor thereof may permeate the resin composition layer and adsorb to the interactive group more efficiently.

The solvent used for the preparation of plating catalyst solution is not particularly limited as long as it can permeate the resin composition layer, but is preferably a water-soluble organic solvent as described below, since water is typically used as a main solvent (dispersant) of the plating catalyst solution. However, it is also possible to use a non-aqueous organic solvent within a certain range as described later, as long as water is used as a main component.

(Water Soluble Organic Solvent)

The water soluble organic solvent used for the plating catalyst solution according to the invention is not particularly limited, as long as the solvent dissolves in water in an amount of 1% by mass or more. Examples of the water soluble organic solvent include ketone-based solvent, ester-based solvent, alcohol-based solvent, ether-based solvent, amine-based solvent, thiol-based solvent and halogen-based solvent.

The ketone-based solvents include acetone, 4-hydroxy-4-methyl-2-pentanone, γ-butyrolactone and hydroxyacetone.

The ester-based solvents include ethyl acetate, ethyl 2-(2-ethoxyethoxy)acetate, ethylene glycol monomethyl ether acetate, diethylene glycol monoethyl ether acetate, methyl cellosolve acetate, ethyl 2-hydroxyethyl acrylate, hydroxypropyl acrylate, methyl glycolate and ethyl glycolate.

The alcohol-based solvents include ethanol, isopropyl alcohol, normal propyl alcohol, 3-acetyl-1-propanol, 2-(allyloxy)ethanol, 2-aminoethanol, 2-amino-2-methyl-1-propanol, (±)-2-amino-1-propanol, 3-amino-1-propanol, 2-dimethylaminoethanol, 2,3-epoxy-1-propanol, ethylene glycol, 2-fluoroethanol, diacetone alcohol, 2-methylcyclohexanol, 4-hydroxy-4-methyl-2-pentanone, glycerin, 2,2′,2″-nitrilotriethanol, 2-pyrdine methanol, 2,2,3,3-tetrafluoro-1′-propanol, 2-(2-aminoethoxy)ethanol, 2-[2-(benzyloxy)ethoxy]ethanol, 2,3-butanediol, 2-butoxyethanol, 2,2′-thiodiethanol, 1,3-butanediol, 1,4-butanediol, 2,3-butanediol, 2-methyl-2,4-pentanediol, 1,3-propanediol, diglycerin, 2,2′-methyliminodiethanol and 1,2-pentanediol.

The ether-based solvents include bis(2-ethoxyethyl)ether, bis[2-(2-hydroxyethoxy)ethyl]ether, 1,2-bis(2-methoxyethoxy)ethane, bis[2-(2-methoxyethoxy)ethyl]ether, bis(2-methoxyethyl)ether, 2-(2-butoxyethoxy)ethanol, 2-[2-(2-chloroethoxy)ethoxy]ethanol, 2-ethoxyethanol, 2-(2-ethoxyethoxy)ethanol, 2-isobutoxy ethanol, 2-(2-isobutoxyethoxy)ethanol, 2-isopropoxyethanol, 2-[2-(2-methoxyethoxy)ethoxy]ethanol, 2-(2-methoxyethoxy)ethanol, 1-ethoxy-2-propanol, 1-methoxy-2-propanol, tripropylene glycol monomethyl ether, methoxy acetate and 2-methoxy ethanol.

The glycol-based solvents include diethylene glycol, triethylene glycol, ethylene glycol, hexaethylene glycol, propylene glycol, dipropylene glycol and tripropylene glycol.

The amine-based solvents include N-methyl-2-pyrolidone and N,N-dimethyl formamide.

The thiol-based solvents include mercaptoacetic acid and 2-mercaptoethanol.

The halogen-based solvents include 3-bromobenzylalcohol, 2-chloroethanol and 3-chloro-1,2-propanediol.

Other than the above examples, various organic solvents shown in the following table may be used as the water soluble organic solvent.

TABLE 1

| | | |
|---|---|---|
| Acrylic acid | Ethyl 2-(dimethylamino)acrylate | Acetylmethylcarbinol |
| 1-amino-4-methylpiperazine | 3-aldehydepyridine | Isobutyric acid |
| Aluminium ethyl acetoacetate | | Ethyl glycol |
| diisopropylate (that of | | |
| water soluble type) | | |
| Ethylene glycol monobutyl ether | Ethylene chlorohydrin | N-ethylmorpholine |
| Ethylenediamine | 3-ethoxy propylamine | Formic acid (86% or more) |
| Isoamyl formate | Acetic acid | 1,4-diaminobutane |
| 1,2-diaminopropane | 1,3-diaminopropane | 3-diethylaminopropylamine |
| N,N-diethylethanolamine | cyclohexylamine | N,N-dimethylacetamide |
| Di-n-butoxy-bis(triethanolaminato)titanium | | Dimethylaminopropylamine |
| 2-dimethylaminoacetoaldehyde | | N,N-dimethyl ethanol amine |
| dimethyl acetal | | |
| 2,5-dimethyl pyrazine | Pyrethrum (for stored grain: | Hydrated hydrazine (79% or |
| | emulsion) | less) |
| Sodium alcoholate (liquid) | Tetramethyl-1,3-diaminopropane | Sodium methoxide |
| 1,1,3-trihydrotetrafluoropropanol | Ethyl lactate | Methyl lactate |
| α-picoline | β-picoline | γ-picoline |
| Hydrazine (79% of less) | Propionic acid | Propylene chlorohydrin |
| Benzylaminopurine (3% emulsion) | Trimethyl borate | Methylaminopropylamine |
| N-methylpiperazine | 2-methylpyrazine | 3-methoxypropylamine |
| 2-mercaptoethanol | Morpholine | Diethylenetriamine |
| N,N-dimethyl acrylamide | Dimethylaminopropyl | Dimethylsulfoxide |
| | methacrylamide | |
| N,N-dimethylaminopropyl | | (−)-D-diisopropyl tartrate |
| acrylamide | | |
| Hydrated hydrazine (80% or more) | Sulfolane(anhydride in a solid state | Thioglycolic acid |
| | is non-dangerous material) | |
| Thiodiglycol | Tetraethylene pentamine | n-tetradecane |
| N,N,N′,N′-tetramethyl-1,6- | | Triethyl phosphate (TEP) |
| hexamethylene diamine | | |
| Triethylene glycol | Triethylene tetramine | Trimethyl phosphate |
| d-valerolactone | Bisaminopropyl piperazine | Hydrazine (80% or more) |
| 2-hydroxyethyl acylate | 2-hydroxyethyl aminopropylamine | Hydroxyethyl pyperazine |
| 4-hydroxy-2-butanone | Vinyltris(β-methoxyethoxy)silane | 2-pyridine methanol |
| 3-pyridine methanol | 4-pyridine methanol | Pyruvic acid |
| Phenethylamine | Formamide | 1,3-butanediol |
| 1,4-butanediol | Butyldiglycol | γ-butyrolactone |
| Furfuryl alcohol | Hexylene glycol | Benzylamine |
| Pentaethylene hexamine | Polyethylene glycol diglycidyl ether (n = about 13 or less) | |
| Polypropylene glycol diglycidyl | | Methacrylic acid |
| ether (n = about 11 or less) | | |
| 2-hydroxyethyl methacrylate | Methyliminobispropylamine | N-methylethanolamine |
| N-methyl-N,N′-diethanolamine | 3-methyl-3-methoxybutyl acetate | β-mercaptopropionic acid |
| Monoethylene glycol acetate | | |

Other applicable organic solvents include, specifically, methyl acetoacetate, ethyl acetoacetate, ethylene glycol diacetate, cyclohexanone, acetylacetone, acetophenone, 2-(1-cyclohexenyl), propylene glycol diacetate, triacetin, diethylene glycol diacetate, dioxane, N-methyl pyrrolidone, dimethyl carbonate and dimethyl cellosolve. From the viewpoint of compatibility with the plating catalyst or the precursor thereof, or the resin composition layer, in particular, a combination of acetone, dimethyl carbonate and dimethyl cellosolve is also preferable.

Other examples of the solvent that may be used in combination include diacetone alcohol, methyl cellosolve, ethyl cellosolve, ethylene glycol tertiary butyl ether, tetrahydrofuran, 1,4-dioxane and n-methyl-2-pyrrolidone.

A non-water-soluble solvent may be mixed with the solvent as mentioned above, at an amount up to the solubility limit to water. For example, dimethyl carbonate may be mixed with water at an amount of up to 12.5%; triacetin may be mixed with water at an amount of up to 7.2%; and cyclohexanone may be mixed with water at an amount of up to 9%.

Among above water soluble organic solvents, as one of preferable embodiments, from the view point of less concern of oxidation due to the catalytic metal, organic solvent not containing alcohol, such as ketone-based solvent, ester-based solvent and ether-based solvent is preferable from the view point of storage stability of the solution as catalytic solution. In particular, acetone, dimethyl carbonate, ethylene glycol dimethyl ether, ethyl 2-(2-ethoxyethoxy)acetate, 1-acetoxy-2-methoxyethane, bis(2-ethoxyethyl)ether (also refer to as diethylene glycol diethyl ether), 1,2-bis(2-methoxyethoxy)ethane, bis[2-(2-methoxyethoxy)ethyl]ether and bis(2-methoxyethyl)ether (also refer to as diethylene glycol dimethyl ether) are preferably exemplified.

The content of the non-water-soluble solvent to be combined with the water soluble organic solvent is preferably in the range of from 0.5 to 40% by mass, more preferably from 5 to 30% by mass, and particularly preferably from 5 to 20% by mass, relative to the total quantity of the plating catalyst liquid.

Further, the content of the water soluble organic solvent, which is a preferable embodiment, is preferably in the range of from 0.1% by mass to 40% by mass, more preferably from 5% by mass to 40% by mass, relative to the total quantity of the plating catalyst liquid, from the viewpoint of permeability to the substance to be plated.

The plating catalyst liquid of the invention may contain other additives in accordance with purposes, in addition to the plating catalyst or the precursor thereof and water which is a main solvent, to such an extent that the effect of the invention is not impaired.

Examples of the additive include acids (inorganic acid such as hydrochloric acid or nitric acid, organic acid such as acetic acid or citric acid), swelling agents (organic compound such as ketones, aldehydes, ethers, esters, or the like), and surfactants (anionic surfactants, cationic surfactants, amphoteric surfactants, nonionic surfactants, low-molecular surfactants, high-molecular surfactants, or the like).

As mentioned above, by contacting the electroless plating catalyst or the precursor thereof to the resin composition layer, the electroless plating catalyst or the precursor thereof may be adsorbed to the interactive group (such as a cyano group) in the resin composition layer by means of an intermolecular force such as van der Waal's force, or a coordination bond by lone-pair electrons.

In view of sufficiently performing the adsorption, the concentration of metal in a dispersion, solution or composition, or metal ion in a solution, is preferably from 0.001 to 50 mass %, more preferably from 0.005 to 30 mass %. The time for contacting is preferably from 30 seconds to 24 hours, more preferably from 1 minute to 1 hour.

Through the aforementioned step (a2), interaction between the interactive group (such as a cyano group) in the resin composition layer and the plating catalyst or the precursor thereof may be achieved.

Step (a3)

In step (a3), a plating film is formed by performing plating to the resin composition layer to which the electroless plating catalyst or the precursor thereof has been applied. The plating film thus formed exhibits excellent electroconductivity and adhesiveness.

Examples of the type of the plating performed in this step include electroless plating and electroplating, and may be selected according to the functions of the plating catalyst or the precursor thereof that has been interacting with the resin composition layer in the previous step (a2).

That is, in this step, either electroplating or electroless plating may be performed to the resin composition layer to which the plating catalyst or the precursor thereof has been applied.

In the invention, it is preferable to perform electroless plating from the viewpoint of improving the formation of a hybrid structure that occurs in the resin composition layer or enhancing the adhesiveness. Further, in order to obtain a plating layer having a desired thickness, it is more preferable to perform electroplating after the electroless plating.

Hereinafter, the plating that is suitably carried out in this step will be described.

(Electroless Plating)

Electroless plating refers to an operation of precipitating a metal by means of a chemical reaction, using a solution in which ions of the metal to be precipitated is dissolved.

The electroless plating in this step is carried out by, for example, washing the substrate to which the electroless plating catalyst has been applied with water to remove excess electroless plating catalyst (metal), and then immersing the substrate in an electroless plating bath. A generally known electroless plating bath may be used as the electroless plating bath.

When a substrate to which an electroless plating catalyst precursor has been provided is immersed in the electroless plating bath, while the electroless plating catalyst precursor has been adsorbed or impregnated in the resin composition layer, the substrate is washed with water to remove excess precursor (metal salt or the like), and then is immersed in the electroless plating bath. In this case, reduction of the plating catalyst precursor and the subsequent electroless plating are carried out in the electroless plating bath. In this case, a generally known electroless plating bath may be used as the electroless plating bath also.

The reduction of the electroless plating catalyst precursor may be carried out in a separate process, prior to the electroless plating, by preparing a catalyst activating solution (reducing solution). The catalyst activating solution is a solution dissolving a reducing agent capable of reducing the electroless plating catalyst precursor (mainly a metal ion) to a zero-valent metal, and the concentration of the reducing agent is generally in the range of 0.1% by mass to 50% by mass, and is preferably in the range of 1% to 30% by mass. Examples of the reducing agent that may be used include boron-based reducing agents such as sodium borohydride and dimethylamineborane, and reducing agents such as formaldehyde and hypophosphorous acid.

The composition of the electroless plating bath generally includes, as main components in addition to a solvent, a metal ion for the plating, a reducing agent, and an additive that enhances the stability of the metal ion (stabilizer). The electroless plating bath may further contain, in addition to the above components, a known additive such as a stabilizer for the plating bath.

The solvent used in the plating bath preferably includes an organic solvent that exhibits high affinity to the resin composition layer having low water absorbability and is highly hydrophobic, for example, the resin composition layer that satisfies at least one of the aforementioned requirements (1) to (4). The type or the content of the organic solvent may be determined in accordance with the properties of the resin composition layer. In particular, when the resin composition layer has a high degree of saturated water absorption rate at a relative humidity of 25° C.-50% (requirement (1)), the content of the organic solvent is preferably small.

Specifically, when the saturated water absorption rate at a relative humidity of 25° C.-50% of the resin composition layer is 0.01 to 0.5% by mass, the content of the organic solvent in the entire solvent in the plating bath is preferably 20 to 80% by mass; when the saturated water absorption rate at a relative humidity of 25° C.-50% of the resin composition layer is 0.5 to 5% by mass, the content of the organic solvent in the entire solvent in the plating bath is preferably 10 to 80% by mass; when the saturated water absorption rate at a relative humidity of 25° C.-50% of the resin composition layer is 5 to 10% by mass, the content of the organic solvent in the entire solvent in the plating bath is preferably 0 to 60% by mass; and when the saturated water absorption rate at a relative humidity of 25° C.-50% of the resin composition layer is 10 to 20% by mass, the content of the organic solvent in the entire solvent in the plating bath is preferably 0 to 45% by mass.

The organic solvent used in the plating bath needs to be miscible with water, and from that standpoint, ketones such as acetone, and alcohols such as methanol, ethanol and isopropanol are preferably used.

Examples of the metal used in the electroless plating bath include copper, tin, lead, nickel, gold, palladium and rhodium, and from the viewpoint of electrical conductivity, copper and gold are preferred.

The optimal reducing agent and additive may be selected in combination with the metal to be used. For example, the electroless plating bath of copper contains CuSO₄ as a copper salt, HCOH as a reducing agent, and a chelating agent that serves as a stabilizer of copper ions such as EDTA or Rochelle salt, and trialkanolamine or the like. The electroless plating bath of CoNiP contains cobalt sulfate or nickel sulfate as a metal salt, sodium hypophosphite as a reducing agent, and sodium malonate, sodium malate or sodium succinate as a complexing agent. The electroless plating bath of palladium contains (Pd(NH₃)₄)Cl₂ as a metal ion, NH₃ or H₂NNH₂ as a reducing agent, and EDTA as a stabilizer. These plating baths may also contain other components than the above-described components.

The thickness of the plating film formed by electroless plating may be controlled by adjusting the concentration of the metal ion in the plating bath, the immersion time in the plating bath, the temperature of the plating bath, or the like. From the viewpoint of electroconductivity, the thickness of the plating film is preferably 0.2 μm or more, and more preferably 0.5 μm or more.

The immersion time in the plating bath is preferably about 1 minute to about 6 hours, and more preferably about 1 minute to about 3 hours.

By observing the cross-section with a scanning electron microscope (SEM), it may be confirmed that microparticles of the electroless plating catalyst or the plating metal are dispersed in the resin composition layer at high density, and that the plating metal is precipitated on the resin composition layer. Since the interface between the substrate and the plating film is in a hybrid state of the polymer and the microparticles, favorable adhesiveness may be achieved even when the interface between the substrate (organic component) and the inorganic substance (catalyst metal or plating metal) is flat and smooth (for example, the roughness is 500 nm or less).

(Electroplating)

In this step, if the plating catalyst or the precursor thereof applied during step (a2) has a function as an electrode, electroplating may be performed to the resin composition layer to which the catalyst or the precursor thereof has been applied.

It is also possible to perform electroplating after performing the above-described electroless plating, by using a plating film that has been formed in the electroless plating as an electrode. In this case, a metal film may be easily formed to a desired thickness based on the plating film having excellent adhesiveness to the substrate. Therefore, it is possible to form a metal film to a desired thickness by performing electroplating after the electroless plating, which is advantageous to use the metal film of the invention in various applications.

The method of performing electroplating according to the invention may be a conventionally known method. Examples of the metal that may be used in the electroplating include copper, chromium, lead, nickel, gold, silver, tin, and zinc. From the viewpoint of electrical conductivity, copper, gold and silver are preferred, while copper is more preferred.

The thickness of the metal film obtained by electroplating may vary according to usage, and may be controlled by adjusting the concentration of the metal contained in the plating bath, current density, or the like. In the case of general electrical wiring lines or the like, the film thickness is preferably 0.5 μm or more, and more preferably 3 μm or more, from the viewpoint of electrical conductivity.

In the invention, by forming a fractal microstructure in the resin composition layer from a metal or a metal salt that is derived from the above-described plating catalyst or the precursor thereof and/or a metal that has precipitated in the resin composition layer by the electroless plating, adhesion between the metal film and the resin composition layer may be further enhanced.

Regarding the amount of metal in the resin composition layer, even higher adhesion may be achieved when the ratio of metal in a portion from the outermost surface of the resin composition layer to a depth of 0.5 μm is 5 to 50% by area, and the arithmetic average roughness Ra (JIS B 0633-2001, ISO 4288 (1996)) at an interface of the resin composition layer and the metal film is 0.05 μm to 0.5 μm, as observed in a photograph of a cross-section of the substrate with a metal microscope.

(Metal Plated Material)

By going through the respective processes of producing a metal plated material of the invention, a metal plated material of the invention may be obtained. According to the third method of producing a metal plated material of the invention, a metal plated material having a metal film formed on both sides may be obtained.

In the metal plated material obtained by the process of producing a metal plated material of the invention, adhesion of the metal layer is less prone to change even at high temperature and high humidity. This metal plated material may be used in various applications such as electromagnetic wave shielding films, coating films, dual-layer CCL (copper clad laminate) materials, and electrical wiring materials.

The method of producing a metal pattern material of the invention includes etching the plating film, which has been formed through steps (a1) to (a3) of the method of producing the metal plated material of the invention, in a patterned manner (step (a4)).

Step (a4)

In step (a4), the plating film (metal film) formed in step (a3) is etched in a patterned manner. Specifically, in this step, a desired metal pattern may be formed by performing etching to remove an unnecessary portion of the plating film that has been formed over the entire surface of the substrate.

The formation of the metal pattern may be conducted by any technique, and examples thereof include a generally known subtractive method or a semi-additive method.

The subtractive method is a method of forming a metal pattern, and the method includes: providing a dry film resist layer on the plating film; forming a dry resist pattern having the same pattern as that of the metal pattern from the dry resist layer by exposing the same to light in a patterned manner and developing the same; and then removing the plating film with an etching solution using the dry film resist pattern as a mask. The material for the dry film resist is not particularly limited, and any of a negative type, a positive type, a liquid-like or a film-like material may be used. The etching method may be any method that is used in the production of printed wiring boards, such as wet etching, dry etching or the like. From the viewpoint of operability, a wet etching method in which a simple device is used is preferred. The etching solution may be, for example, an aqueous solution of cupric chloride, ferric chloride, or the like.

The semi-additive method is a method of forming a metal pattern, and the method includes: providing a dry film resist layer on the plating film; forming a dry film resist pattern having the same pattern as that of a non-metal pattern portion from the dry film resist layer by exposing the same to light in a patterned manner and developing the same; performing electroplating by using the dry film resist pattern as a mask; performing quick etching after removing the dry film resist pattern; and then removing the plating film in a patterned manner. The materials for the dry film resist, etching solution or the like may be the same materials as those used in the subtractive method. The method of performing electroplating may be the method as mentioned above.

By going through steps (a1) to (a4) described above, a metal pattern material having a desired metal pattern may be produced.

It is also possible to produce a metal pattern material by a full-additive method, in which the resin composition layer is formed in a patterned manner in step (a1) or step (a1′), and the subsequent steps (a2) and (a3) are conducted to the patterned resin composition layer.

It is possible to form the resin composition layer in a patterned manner in step (a1) or step (a1′), specifically, by exposing the resin composition layer to light in a patterned manner, and developing the unexposed portion and removing the same.

The development may be performed by, for example, immersing the material in a solvent capable of dissolving a component used for forming the resin composition layer such as the specific compound (or cyano group-containing polymerizable polymer). The time for immersion is preferably from 1 minute to 30 minutes.

Alternatively, the resin composition layer may be formed at step (a1) or step (a1′) by directly conducting patterning by a known application method, such as a gravure printing method, an inkjet method, or a spray coating method using a mask; applying energy to the same; and then washing (developing) the same.

The subsequent steps (a2) and (a3) for forming a plating film on the resin composition layer that has been formed in a patterned manner may be the same as those described above.

(Metal Pattern Material)

The metal pattern material of the invention is obtained by the method of producing a metal pattern material of the invention, and has a metal pattern that exhibits excellent adhesion to the substrate.

Since the resin composition layer has low water absorbance and is highly hydrophobic, an exposed portion of the same (portion to which no metal pattern is formed) exhibits excellent insulation reliability.

The metal pattern material of the invention preferably has a metal film (plating film) on the entire surface or a portion of the substrate having a surface roughness of 500 nm or less (more preferably 100 nm or less). Furthermore, it is also preferable that the adhesiveness between the substrate and the metal pattern is 0.2 kN/m or more. These characteristics mean that the metal pattern material exhibits excellent adhesiveness between the substrate and the metal pattern, even if the surface of the substrate is flat and smooth.

Here, the surface roughness of the substrate is a value measured by cutting the substrate in a perpendicular manner to the substrate surface, and observing a cross-section thereof with an SEM.

More specifically, it is preferable that the surface of the substrate has a Rz as measured according to JIS B 0601 (ISO 4287 (1997)), which is a “difference between the average value of Z data of the five highest points and the average value of Z data of the five lowest points in a designated plane”, of 500 nm or less.

The value of adhesiveness between the substrate and the metal film may be measured by adhering a copper plate (thickness: 0.1 mm) to the surface of the metal film (metal pattern) with an epoxy-based adhesive (trade name: ARALDITE, manufactured by Huntsman Advanced Materials), drying the same for 4 hours at 140° C., and then performing a 90-degree peeling test based on JIS C 6481, or directly peeling off the edge portion of the metal film itself and performing the 90-degree peeling test based on JIS C 6481.

The metal pattern material obtained by the method of producing a metal pattern material of the invention may be used, for example, in semiconductor chips, electric wiring boards, FPCs, COFs, TABs, antennas, multilayer wiring substrates, mother boards, or the like.

In particular, the wiring substrate having a metal pattern produced by the method of the invention can form wiring lines that exhibit excellent adhesion to a flat and smooth substrate and excellent high-frequency characteristics. Moreover, excellent insulating reliability among the fine, high-density wiring lines may be achieved.

The wiring substrate obtained in the invention may be formed so as to have a multilayer structure by forming another resin composition layer (interlayer insulation film) on the metal pattern material, and then forming another wiring (metal pattern) thereon. Further, a solder resist may be formed on the surface of the metal pattern material.

Example of the material for the interlayer insulating film that may be used in the invention include an epoxy resin, an aramid resin, a crystalline polyolefin resin, a non-crystalline polyolefin resin, a fluorine-containing resin (polytetrafluoroethylene, perfluoropolyimide, perfluoroamorphous resin or the like), a polyimide resin, polyethersulfone, polyphenylenesulfide, poyletheretherketone, and a liquid crystal resin.

Among these, an epoxy resin, a polyimide resin and a liquid crystal resin are preferably included in the interlayer insulating layer from the viewpoints of dimensional stability, heat resistance, electrical insulating property, or the like. One specific example is ABF GX-13 (trade name, manufactured by Ajinomoto Fine-Techno Co., Inc.).

Details of the solder resist that may be used for protecting the wiring formed on the surface of the metal pattern material are described, for example, JP-A No. 10-240150 and JP-A No. 2003-222993, and the method described therein may be applied to the invention, as desired. The solder resist may be a commercial product and specific examples thereof include PFR 800 and PSR 4000 (trade name, manufactured by Taiyo Ink Mfg, Co., Ltd.) and SR 7200G (trade name, manufactured by Hitachi Chemical Co., Ltd.).

The photosensitive resin composition of the invention may also exhibit favorable adhesiveness to the aforementioned interlayer insulating film or solder resist film, by the functions of the compound included in the composition selected from a synthesis rubber, an epoxy acrylate monomer, or a polymerizable monomer having a benzyl alcohol group.

### EXAMPLES

The invention will be explained in further details with reference to the following Examples. However, the invention is not limited thereto. The term “%” and “part” refer to “% by mass” and “part by mass”, respectively, unless otherwise specified.

### Example 1

### Preparation of Substrate

A base material was obtained by attaching, as an electrically insulating layer, an epoxy-based insulating film (GX-13, trade name, manufactured by Ajinomoto Fine-Techno Co., Inc., thickness: 45 μm) to a glass epoxy substrate by a vacuum laminator by heating at 100 to 110° C. and pressing at 0.2 MPa.

(Formation of Polymerization Initiation Layer)

A composition for polymerization initiation layer was prepared by mixing 11.9 parts of JER 806 (bisphenol F-type epoxy resin, trade name, manufactured by Japan Epoxy Resins Co., Ltd.), 4.7 parts of LA 7052 (PHENOLITE, trade name, curing agent, manufactured by DIC Corporation), 21.7 parts of YP 50-35 EK (phenoxy resin, trade name, manufactured by Tohto Kasei Co., Ltd.), 61.6 parts of cyclohexanone, and 0.1 part of 2-ethyl-4-methyl imidazole (curing promotor), and then filtering the mixture by a filter cloth (mesh: #200).

The composition was applied onto the base material by a spin coater (rotated at 300 rpm for 5 seconds and then at 1,500 rpm for 25 seconds) and then dried at 170° C. to cure, thereby obtaining substrate A1. The thickness of the polymerization initiation layer after the curing was 1.3 m. The surface roughness (Ra) of substrate A1 was 0.5 μm (per 200 μm²).

<Formation of Resin Composition Layer>

(Preparation of Polymer A Having Polymerizable Group and Interactive Group)

35 g of N,N-dimethylacetoamide were placed into a 1000-ml three neck flask, and was heated to 75° C. under a nitrogen stream. Then, a solution of 35 g of N,N-dimethyladetoamide containing 6.60 g of 2-hydroxyethylacrylate (a product from Tokyo Chemical Industry Co., Ltd.), 28.4 g of 2-cyanoethylacrylate, and 0.65 g of V-601 (trade name, a product from Wako Pure Chemical Industries, Ltd.) was dropped into the flask over 2.5 hours. After the completion of dropping, the mixture was heated to 80° C. and was stirred for 3 hours. Thereafter, the reaction solution was cooled to room temperature.

To the above reaction solution, 0.29 g of ditertiarybutyl hydroquinone, 0.29 g of dibutyltin dilaurate, 18.56 g of KARENZ AOI (trade name, a product from Showa Denko K.K.) and 19 g of N,N-dimethylacetoamide were added and reacted at 55° C. for 4 hours. Thereafter, 3.6 g of methanol was added to the reaction solution and was further reacted for 1.5 hours. After the completion of reaction, the reaction solution was subjected to reprecipitation with a mixture of ethyl acetate:hexane (1:1) to recover a solid. 32 g of polymer A having a polymerizable group and an interactive group (weight average molecular weight: 62,000) were thus obtained.

<Preparation of Application Composition (Photosensitive Resin Composition 1)>

To 10 parts of acetonitrile solution containing 7% of polymer A, a synthetic rubber (NIPOL 1041, trade name, a product from Zeon Corporation) was added at an amount of 20% with respect to the solid content of polymer A. Acetone was further added to the mixture as a solvent, and an application composition (photosensitive resin composition 1) having a solid content concentration of 6% was prepared.

(Generation of Graft Polymer)

Photosensitive resin composition 1 was applied onto the polymerization initiation layer of substrate A1 by a spin coater (rotated at 300 rpm for 5 seconds and then at 750 rpm for 20 seconds), and then dried at 80° C. for 30 minutes.

After the drying, the polymerization initiation layer of substrate A1 was irradiated with light using a UV exposure device (type: UVF-502S, lamp: UXM-501MD, manufactured by San-ei Electric Co., Ltd.) for 100 seconds to generate a graft polymer on the entire surface of the polymerization initiation layer. The irradiation power as measured by a UV integrated light intensity meter (UIT 150 with a light-receiving sensor UVD-S254, manufactured by Ushio Lighting, Inc.) was 10 mW/cm². The integrated exposure amount was 1,000 mJ.

Thereafter, substrate A1 with a graft polymer generated thereon was immersed in acetonitrile for 5 minutes while stirring, and was washed with distilled water. Substrate A2 having a resin composition layer formed thereon was thus obtained. The thickness of the resin composition layer was 0.6 μm.

(Measurement of Physical Properties of Resin Composition Layer)

The physical properties of the obtained resin composition layer were measured in accordance with the aforementioned method. As a result, the surface contact angle after dropping 5 μL of distilled water onto the resin composition layer and leaving the same to stand for 15 seconds in a relative humidity environment of 25° C.-50% was 60°, indicating that the resin composition layer had a hydrophobic surface.

<Application of Plating Catalyst>

Substrate A2 was immersed in a mixed solution of water and acetone containing 0.5% of palladium nitrate (mixing ratio of water/acetone by weight was 6/4, hereinafter referred to as catalyst solution A) at 25° C. for 30 minutes. Substrate A2 was then washed with a mixed solution of water/acetone (6/4 by weight) and with distilled water for 1 to 2 minutes, respectively.

<Electroless Plating>

Substrate A2 to which a plating catalyst had been applied was subjected to electroless plating with an electroless plating solution (I) having the following composition, using commercially available electroless copper plating solutions (THRU-CUP PGT, trade name, manufactured by C. Uyemura & Co., Ltd.), at 26° C. for 30 minutes. The thickness of the obtained electroless copper plating film was 0.5 μm (as measured by a gravimetric method).

(Composition of electroless plating solution (1))

| | |
|---|---|
| Distilled water | approx. 60% by volume |
| PGT-A | 9.0% by volume |
| PGT-B | 6.0% by volume |
| PGT-C | 3.5% by volume |
| Formaldehyde solution* | 2.3% by volume |

Finally, the total amount of electroless plating solution (1) was adjusted at a liquid level with distilled water to 100% by volume.
*The formaldehyde solution was a product from Wako Pure Chemical Industries, Ltd. (special grade).

<Electroplating>

Subsequently, electroplating was performed in a copper electroplating bath having the following composition, using the copper electroless plating film as a feeding layer, at 3 A/dm² for 30 minutes. The thickness of the obtained copper electroplating film was 19.5 μm.

(Composition of electroless plating bath)

| | | |
|---|---|---|
| Copper sulfate | 38 | g |
| Sulfuric acid | 95 | g |
| Hydrochloric acid | 1 | mL |
| Copper Gleam PCM | 3 | mL |
| (trade name, manufactured by Meltex, Inc.) | | |
| Water | 500 | g |

(Evaluation of Adhesiveness)

After subjecting the obtained plating film to a baking treatment at 100° C. for 30 minutes and then at 170° C. for 1 hour, the 90° peel strength of the obtained plating film was measured at a width of 5 mm, using an autograph (AGS-J, trade name, manufactured by Shimadzu Corporation) at a tensile strength of 10 mm/min. The result was 0.77 kN/m.

<Formation of Metal Pattern, Attachment of Solder Resist and Insulation Reliability Test>

After performing electroplating, the substrate was subjected to a heat treatment at 180° C. for 1 hour. Thereafter, a dry resist film (RY3315, trade name, manufactured by Hitachi Chemical Co., Ltd., thickness: 15 μm) was attached to the surface of the substrate using a vacuum laminator (MVLP-600, trade name, manufactured by Meiki Co., Ltd.) at 70° C. and 0.2 MPa. Subsequently, a glass mask that can form a comb-shaped wiring having a L/S as stipulated in JPCA-ET01 of 75 μm/75 μm (based on JPCA-BU01-2007, Pattern FB) was adhered to the dry resist film laminated on the substrate, and the resist was irradiated with light at 70 mJ using an exposing device (center wavelength: 405 nm). After the exposure, the substrate was developed by spraying a 1% aqueous solution of Na₂CO₃ at a pressure of 0.2 MPa. Thereafter, the substrate was washed with water and dried, and a resist pattern for subtractive method was formed on the copper plating film.

Then, the substrate with the resist pattern was etched by immersing in an aqueous solution of FeCl₃/HCl (etching solution) at 40° C., and the copper plating layer at a portion to which no resist pattern was formed was removed. Thereafter, a 3% aqueous solution of NaOH was sprayed to the substrate at a pressure of 0.2 MPa to allow the resist pattern to swell and remove from the substrate, and the substrate was neutralized by a 10% aqueous solution of sulfuric acid and washed with water. The comb-shaped wiring was thus obtained.

Further, a solder resist (PFR800, trade name, manufactured by Taiyo Ink Mfg. Co., Ltd.) was attached to the comb-shaped wiring by vacuum laminating at 70° C. and 0.2 MPa, and light energy of 420 mJ was applied thereto by an exposing device (central wavelength: 365 nm). At this time, a portion to which a solder was to be applied in the subsequent insulation reliability test was masked with a light-shielding tape. Thereafter, the substrate was subjected to a heat treatment at 80° C. for 10 minutes, and was developed by spraying a 1% aqueous solution of Na₂CO₃ to the surface of the substrate at a pressure of 0.2 MPa, and then washed with water and dried. Subsequently, light energy of 1,000 mJ was again applied to the substrate using an exposing device (central wavelength: 365 nm). Finally, the substrate was subjected to a heat treatment at 150° C. for 1 hour, thereby obtaining a comb-shaped wiring (metal pattern material) for measuring an inter-wiring insulating reliability at a portion covered with the solder resist.

Using the substrate having the comb-shaped wiring, an insulating reliability test was performed in accordance with JPCA-ET01 (general rule) and ET07 (highly accelerated stress test at high temperature/high humidity and normal conditions) of Japan Electronics Packaging and Circuits Association (JPCA) Standard (environmental testing procedure for printed wiring boards). Specifically, the substrate was placed in a HAST tester (AM1-150S-25 (EHS-211-MD), trade name, manufactured by Espec Corp.), and the test was conducted at 130° C.-85% relative humidity (unsaturated) with an applied voltage of 20V for 200 hours, by inspecting the insulating resistance in the tester and the surface conditions between the wiring lines. As a result, the insulating resistance in the tester was acceptable (10⁶Ω or more) and dendrites were slightly observed but not so much as causing insulating defects (grade: B).

### Example 2

A metal plated material was prepared in a similar manner to Example 1, except that the same amount of synthetic resin (XER-91, trade name, manufactured by JSR Corporation) was used in place of NIPOL 1041, and the evaluation was conducted in a similar manner to Example 1. As a result, the surface contact angle of the resin composition layer was 650, indicating that the layer had a hydrophobic surface. The thickness of the obtained copper electroless plating film was 0.5 μm (according to a gravimetric method). The adhesion of the plating film was 0.72 kN/m. The insulating resistance was acceptable (10⁶Ω or more) and dendrites were slightly observed but not so much as causing insulating defects (grade: B).

### Example 3

A metal plated material was prepared in a similar manner to Example 1, except that the same amount of glycidyl methacrylate as an epoxy acrylate monomer (manufactured by Tokyo Chemical Industry, Co., Ltd.) was used in place of NIPOL 1041, and the evaluation was conducted in a similar manner to Example 1. As a result, the surface contact angle of the resin composition layer was 62°, indicating that the layer had a hydrophobic surface. The thickness of the obtained copper electroless plating film was 0.5 μm (according to a gravimetric method). The adhesion of the plating film was 0.74 kN/m. The insulating resistance was acceptable (10⁶Ω or more) and dendrites were slightly observed but not so much as causing insulating defects (grade: B).

### Example 4

A metal plated material was prepared in a similar manner to Example 1, except that the same amount of 1-(meth)acryloyloxy-2,6-bis(hydroxymethyl)-benzene as a polymerizable monomer having a benzyl alcohol group (prepared by the following process) was used in place of NIPOL 1041, and the evaluation was conducted in a similar manner to Example 1. As a result, the surface contact angle of the resin composition layer was 62°, indicating that the layer had a hydrophobic surface. The thickness of the obtained copper electroless plating film was 0.5 μm (according to a gravimetric method). The adhesion of the plating film was 0.65 kN/m. The insulating resistance was acceptable (10⁶Ω or more) and dendrites were slightly observed but not so much as causing insulating defects (grade: B).

(Preparation of Polymerizable Monomer Having Benzyl Alcohol Group)

2 L of ethyl acetate, 50 g of p-xylylene glycol (manufactured by Wako Pure Chemical Industries, Ltd) and 7.1 g of pyridine were placed in a 5-L three neck flask. Then, 8.1 g of acryloyl chloride (manufactured by Tokyo Chemical Industry, Co., Ltd.) were dropped in the flask over 30 minutes. After the completion of dropping, the temperature of mixture was decreased back to room temperature and the mixture was stirred for 3 hours. Subsequently, 2 L of water were added to the reaction solution to separate an ethyl acetate layer, and the remaining was washed with 1 L of saturated sodium bicarbonate water, 1 L of distilled water and 1 L of saturated salt water, and then dried with magnesium sulfate. Thereafter, the solvent was distilled away and the resultant was purified by column chromatography, thereby recovering 9 g of a monomer.

### Example 5

A metal plated material was prepared in a similar manner to Example 1, except that photosensitive resin composition 2 in which glycidyl methacrylate (an epoxy acrylate monomer, manufactured by Tokyo Chemical Industry, Co., Ltd.) of the same amount as NIPOL 1041 was further added to photosensitive resin composition 1 was used in place of photosensitive resin composition 1, and the evaluation was conducted in a similar manner to Example 1. As a result, the surface contact angle of the resin composition layer was 65°, indicating that the layer had a hydrophobic surface. The thickness of the obtained copper electroless plating film was 0.5 μm (according to a gravimetric method). The adhesion of the plating film was 0.75 kN/m. The insulating resistance was acceptable (10⁶Ω or more) and dendrites were hardly observed (grade: A).

### Example 6

Substrate A3 was prepared using photosensitive resin composition 2 as prepared in Example 5. A metal plated material was prepared in a similar manner to Example 1, except that substrate A3 was used in place of substrate A1 and the application of plating catalyst was performed using catalyst solution B (prepared by the following process). The evaluation was conducted in a similar manner to Example 1. As a result, the thickness of the obtained copper electroless plating film was 0.5 μm (according to a gravimetric method). The adhesion of the plating film was 0.74 kN/m. The insulating resistance was acceptable (10⁶Ω or more) and dendrites were hardly observed (grade: A).

(Preparation of Catalyst Solution B)

Catalyst solution B (0.25% palladium catalyst solution) was prepared by dissolving 0.25 parts of palladium acetate in a mixed solution of pure water: 60% aqueous solution of nitric acid: diethylene glycol diethyl ether (DEGDE, bis(2-ethoxyethyl)ether) at a mass ratio of 2:1:2.

The nitric acid (60% aqueous solution) was a product from Wako Pure Chemical Industries, Ltd., nitric acid (1.38) Wako special grade; the DEGDE was a product from Wako Pure Chemical Industries, Ltd., bis(2-ethoxyethyl)ether, Wako first grade; and the palladium acetate was a product from Wako Pure Chemical Industries, Ltd., Wako special grade.

(Application of Catalyst)

Substrate A3 was immersed in catalyst solution B at 25° C. for 5 minutes, and was washed with distilled water for 2 minutes.

Application of plating catalyst was performed in a similar manner to Example 6, using substrate A3 prepared in Example 5.

Thereafter, a metal film was formed on the substrate in a similar manner to Example 1, except that the electroless plating was performed in the following manner using electroless plating solution (2) (having the following composition). Electroless plating solution (2) was prepared using commercially available electroless copper plating solutions (OPC Copper T, trade name, manufactured by Okuno Chemical Industries Co., Ltd.).

(Composition of electroless plating solution (2))

| | |
|---|---|
| Distilled water | approx. 60% by volume |
| T-1 solution | 6.0% by volume |
| T-2 solution | 1.2% by volume |
| T-3 solution | 10.0% by volume |

Finally, the total amount of electroless plating solution (2) was adjusted at a liquid level with distilled water to 100% by volume.

Substrate A3 was immersed in electroless plating solution (2) at 30° C. for 25 minutes to perform electroless plating. The thickness of the obtained electroless copper plating film was 0.7 μm (according to a gravimetric method). The adhesion of the plating film was 0.75 kN/m. The insulating resistance was acceptable (10⁶ or more) and dendrites were hardly observed (grade: A).

### Example 8

Substrate A3 was subjected to application of plating catalyst using catalyst solution B in a similar manner to Example 6. Thereafter, electroless plating was performed using electroless plating solution (2) in a similar manner to Example 7. Thereafter, a metal pattern was formed in accordance with the conditions of Example 1, and an insulating film (ABF GX-13, manufactured by Ajinomoto Fine-Techno Co., Inc.) was attached thereto instead of the solder resist (PFR800) in accordance with the following process. The evaluation was conducted in a similar manner to Example 1. As a result, the thickness of the obtained copper electroless plating film was 0.7 μm (according to a gravimetric method). The adhesion of the plating film was 0.73 kN/m. The insulating resistance was acceptable (10⁶Ω or more) and dendrites were hardly observed (grade: A).

(Formation of Insulating Film)

An insulating film (ABF GX-13, manufactured by Ajinomoto Fine-Techno Co., Inc.) was attached to the comb-shaped wiring prepared in a similar manner to Example 1 using a vacuum laminator (MVLP-600, trade name, manufactured by Meiki Co., Ltd.) at 100° C. and 0.5 MPa. Thereafter, a heat treatment was performed at 180° C. for 1 hour, thereby obtaining a comb-shaped wiring covered with the insulating film for measuring inter-wiring insulating reliability (metal pattern material).

The aforementioned results are described in the following Table 2. In Table 2, the solder resist is referred to as “SR” and the interlayer insulating film is referred to as “insulating film”, respectively.

TABLE 2

| | | Catalyst | Plating | Thickness | Adhesion | | Insulation | |
|---|---|---|---|---|---|---|---|---|
| | Compound | solution | solution | (μm) | (kN/m) | Top layer | resistance | Dendrites |
| Example 1 | NIPOL 1041 | Catalyst | Plating | 0.5 | 0.77 | SR | 10⁶ Ω | B |
| | (synthetic rubber) | solution A | solution (1) | | | | or more | |
| Example 2 | XER-91 | Catalyst | Plating | 0.5 | 0.72 | SR | 10⁶ Ω | B |
| | (synthetic rubber) | solution A | solution (1) | | | | or more | |
| Example 3 | glycidiyl methacrylate | Catalyst | Plating | 0.5 | 0.74 | SR | 10⁶ Ω | B |
| | (epoxy acrylate | solution A | solution (1) | | | | or more | |
| | monomer) | | | | | | | |
| Example 4 | polymerizable | Catalyst | Plating | 0.5 | 0.65 | SR | 10⁶ Ω | B |
| | monomer having | solution A | solution (1) | | | | or more | |
| | benxyl alcohol group | | | | | | | |
| Example 5 | NIPOL 1041 | Catalyst | Plating | 0.5 | 0.75 | SR | 10⁶ Ω | A |
| | glycidyl methacrylate | solution A | solution (1) | | | | or more | |
| Example 6 | NIPOL 1041 | Catalyst | Plating | 0.5 | 0.74 | SR | 10⁶ Ω | A |
| | glycidyl methacrylate | solution B | solution (1) | | | | or more | |
| Example 7 | NIPOL 1041 | Catalyst | Plating | 0.7 | 0.75 | SR | 10⁶ Ω | A |
| | glycidyl methacrylate | solution B | solution (2) | | | | or more | A |
| Example 8 | NIPOL 1041 | Catalyst | Plating | 0.7 | 0.73 | Insulating | 10⁶ Ω | A |
| | glycidyl methacrylate | solution B | solution (2) | | | film | or more | |
| Ref. Example 1 | — | Catalyst | Plating | 0.5 | 0.72 | SR | 10⁶ Ω | C |
| | | solution A | solution (1) | | | | or more | |
| Ref. Example 2 | — | Catalyst | Plating | 0.5 | 0.72 | Insulating | 10⁶ Ω | C |
| | | solution A | solution (1) | | | film | or more | |

As shown in Table 2, the metal plated material produced using the photosensitive resin composition of the invention exhibit excellent adhesion of the plating film to the resin composition layer and excellent inter-wising insulation reliability. Moreover, Examples 5 to 8 in which a synthetic resin and an epoxy acrylate monomer are used in combination exhibit further improved properties as compared to Examples 1 to 4.

### Reference Example 1

A metal plated material was prepared in a similar manner to Example 1, except that NIPOL 1041 was not added to photosensitive resin composition 1. The evaluation was conducted in a similar manner to Example 1. As a result, the surface contact angle of the resin composition layer was 580, indicating that the layer had a hydrophobic surface. The adhesion of the plating film was 0.72 kN/m. The insulating resistance was acceptable (10⁶Ω or more) and dendrites were observed but not so much as causing insulating defects (grade: C).

### Reference Example 2

A metal plated material was prepared in a similar manner to Example 1, except that NIPOL 1041 was not added to photosensitive resin composition 1 and that the top layer was changed to the insulating film used in Example 8. The evaluation was conducted in a similar manner to Example 1. As a result, the surface contact angle of the resin composition layer was 58°, indicating that the layer had a hydrophobic surface. The adhesion of the plating film was 0.72 kN/m. The insulating resistance was acceptable (10⁶Ω or more) and dendrites were observed but not so much as causing insulating defects (grade: C).

In view of above, Examples 1 to 8 exhibit improved inter-wiring insulation reliability even under severe conditions, as compared with Reference Examples 1 and 2 (metal plated materials prepared from a conventional photosensitive resin composition that does not include a synthetic resin, an epoxy acrylate monomer or a polymerizable monomer having a benzylalcohol group).

All publications, patent applications, and technical standards mentioned in this specification are herein incorporated by reference to the same extent as if each individual publication, patent application, or technical standard was specifically and individually indicated to be incorporated by reference.

What is claimed is:

1. A photosensitive resin composition comprising: a polymer comprising a polymerizable group and a functional group that interacts with a plating catalyst or a precursor thereof so as to form a coordination bond; and at least one selected from the group consisting of a synthetic rubber, an epoxy acrylate monomer, and a polymerizable monomer having a benzyl alcohol group.

2. The photosensitive resin composition according to claim 1, wherein the polymer comprises a cyano group.

3. The photosensitive resin composition according to claim 1, wherein the polymer comprises a unit represented by the following formula (1) and a unit represented by the following formula (2): 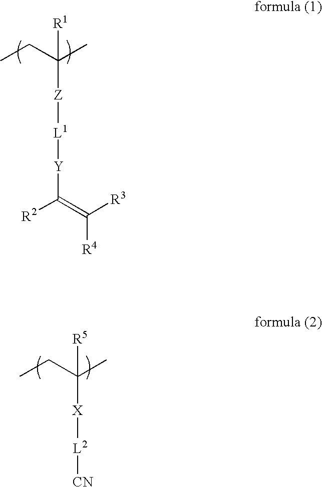
wherein in formulae (1) and (2), R¹ to R⁵ each independently represent a hydrogen atom, or a substituted or unsubstituted alkyl group; X, Y and Z each independently represent a single bond, a substituted or unsubstituted divalent organic group, an ester group, an amide group, or an ether group; and L¹ and L² each independently represent a substituted or unsubstituted divalent organic group.

4. The photosensitive resin composition according to claim 3, wherein the unit represented by formula (1) comprises a unit represented by the following formula (3): 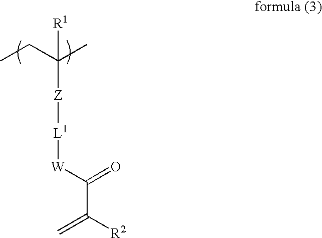
wherein in formula (3), R¹ and R² each independently represent a hydrogen atom, or a substituted or unsubstituted alkyl group; Z represents a single bond, a substituted or unsubstituted divalent organic group, an ester group, an amide group, or an ether group; W represents an oxygen atom, or NR (wherein R represents a hydrogen atom or an alkyl group); and L¹ represents a substituted or unsubstituted divalent organic group.

5. The photosensitive resin composition according to claim 3, wherein the unit represented by formula (2) comprises a unit represented by the following formula (5): 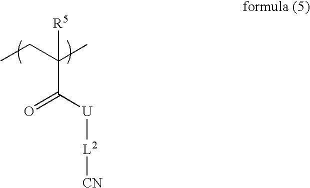
wherein in formula (5), R⁵ represents a hydrogen atom, or a substituted or unsubstituted alkyl group; U represents an oxygen atom, or NR′ (wherein R′ represents a hydrogen atom or an alkyl group); and L² represents a substituted or unsubstituted divalent organic group.

6. The photosensitive resin composition according to claim 1, wherein the composition comprises a synthetic rubber.

7. The photosensitive resin composition according to claim 1, wherein the composition comprises a synthetic rubber and at least one selected from the group consisting of an epoxy acrylate monomer and a polymerizable monomer having a benzyl alcohol group.

8. A laminate comprising a substrate and a resin composition layer formed from the photosensitive resin composition according to claim 1.

9. A method of producing a metal coated material, the method comprising:
forming a resin composition layer from the photosensitive resin composition according to claim 1 on a substrate;
applying a plating catalyst or a precursor thereof to the resin composition layer; and
performing plating to the plating catalyst or the precursor thereof.

10. The method according to claim 9, wherein the formation of the resin composition layer comprises allowing the polymer to directly chemically bond to the substrate.

11. The method according to claim 9, wherein the plating is performed by electroless plating.

12. A metal coated material obtained by the method according to claim 9.

13. A method of producing a metal pattern material, the method comprising etching a plating film of a metal coated material obtained by the method according to claim 9 in a patterned manner.

14. A metal pattern material obtained by the method according to claim 13.

15. A wiring substrate comprising a wiring formed from a metal pattern obtained by the method according to claim 13.
